(19) United States
(12) Patent Application Publication
(10) Pub. No.: US 2024/0063238 A1
(43) Pub. Date: Feb. 22, 2024

(54) SOLID-STATE IMAGING DEVICE AND ELECTRONIC DEVICE

(71) Applicant: SONY SEMICONDUCTOR SOLUTIONS CORPORATION, Kanagawa (JP)

(72) Inventor: Shunsuke MARUYAMA, Kanagawa (JP)

(21) Appl. No.: 18/270,356

(22) PCT Filed: Dec. 21, 2021
(86) PCT No.: PCT/JP2021/047329

§ 371 Date: Jun. 29, 2023

(30) Foreign Application Priority Data
Jan. 28, 2021 (JP) 2021-012381

(51) Int. Cl. H01L 27/146; H04N 25/10; H04N 25/79

(52) U.S. Cl. CPC H01L 27/14623; H04N 25/10; H04N 25/79; H01L 27/14652; H04N 25/78

(57) ABSTRACT

A signal for two wavelengths of infrared light and visible light is obtained. This solid-state imaging device includes a pixel region in which a plurality of pixels is arranged in a matrix, in which the plurality of pixels includes a first pixel and a second pixel, the first pixel includes a first light transmitting part that is provided on a light incident surface side of a first compound semiconductor layer and transmits infrared light and visible light, and a first photoelectric conversion element that is provided in the first compound semiconductor layer and photoelectrically converts the infrared light and the visible light that have passed through the first light transmitting part, and the second pixel includes a second light transmitting part including a second compound semiconductor layer, the second light transmitting part being provided on the light incident surface side of the first compound semiconductor layer and transmitting the infrared light and blocking the transmission of the visible light, and a second photoelectric conversion element that photoelectrically converts the infrared light that has passed through the second light transmitting part.

### TECHNICAL FIELD

The present technology (technology according to the present disclosure) relates to a solid-state imaging device and an electronic device, and particularly relates to a technology effective when applied to a solid-state imaging device including a photoelectric conversion element provided in a compound semiconductor layer and an electronic device including the solid-state imaging device.

### BACKGROUND ART

As a solid-state imaging device, an InGaAs image sensor including a photoelectric conversion element provided in a compound semiconductor layer containing InGaAs is known. In general, in a case where a plurality of wavelength components is obtained by such an InGaAs image sensor, there are a method in which a plurality of sensors is provided to separate light and a method in which in a case of a single sensor, light sources or filters are switched in a time-division manner.

On the other hand, it is known that the InGaAs image sensor is formed by depositing InGaAs on an InP substrate. Then, for a structure that is irradiated from the InP substrate side, it is known that the sensitivity of 950 nm or less changes in a manner that depends on a film thickness (thickness) of InP.

Note that prior art documents related to the present technology include the following Patent Documents 1 to 3.
Patent Document 1 discloses a technique in which in a light receiving element used for optical communication that handles signals of two wavelengths of λ1 and λ2, a filter layer having a band gap of λ1>λg>λ2 is provided on a substrate.
Patent Document 2 discloses a semiconductor light receiving element including a filter in which InGaAsP and a group III-V semiconductor are alternately stacked.
Patent Document 3 discloses a technique in which a notch filter (band cut) is introduced into an infrared camera system.

### CITATION LIST

### Patent Document

Patent Document 1: Japanese Patent Application Laid-Open No. 2000-036615
Patent Document 2: Japanese Patent Application Laid-Open No. 2003-234494
Patent Document 3: Japanese Patent Application Laid-Open No. 2017-083443

### SUMMARY OF THE INVENTION

### Problems to be Solved by the Invention

The method in which a plurality of sensors is provided to separate light, however, makes the system larger and makes the cost higher. Furthermore, in the method in which light sources or filters are switched by a single sensor in a time-division manner, it is difficult to obtain a plurality of wavelengths at a time.

It is therefore an object of the present technology to provide a novel solid-state imaging device and electronic device capable of obtaining a signal for two wavelengths of infrared light and visible light.

### Solutions to Problems

(1) A solid-state imaging device according to an aspect of the present technology includes a pixel region in which a plurality of pixels is arranged in a matrix, in which the plurality of pixels includes a first pixel and a second pixel, the first pixel includes a first light transmitting part that is provided on a light incident surface side of a first compound semiconductor layer and transmits infrared light and visible light, and a first photoelectric conversion element that is provided in the first compound semiconductor layer and photoelectrically converts the infrared light and the visible light that have passed through the first light transmitting part, and the second pixel includes a second light transmitting part including a second compound semiconductor layer, the second light transmitting part being provided on the light incident surface side of the first compound semiconductor layer and transmitting the infrared light and blocking the transmission of the visible light, and a second photoelectric conversion element that photoelectrically converts the infrared light that has passed through the second light transmitting part.

(2) An electronic device according to another aspect of the present technology includes the solid-state imaging device, an optical lens that forms an image of image light from a subject on an imaging surface of the solid-state imaging device, and a signal processing circuit that performs signal processing on a signal output from the solid-state imaging device.

### BRIEF DESCRIPTION OF DRAWINGS

FIG. 1 is a schematic plan layout diagram illustrating a configuration example of a solid-state imaging device according to a first embodiment of the present technology.

FIG. 2 is a block diagram illustrating the configuration example of the solid-state imaging device according to the first embodiment of the present technology.

FIG. 3 is a transparent circuit diagram illustrating a configuration example of a readout circuit of the solid-state imaging device according to the first embodiment of the present technology.

FIG. 4A is a schematic cross-sectional view of a main part illustrating the configuration example of the solid-state imaging device according to the first embodiment of the present technology.

FIG. 4B is a schematic plan view illustrating an arrangement pattern of a pixel including a first light transmitting part and a pixel including a second light transmitting part.

FIG. 5 is a characteristic chart showing dependency on a film thickness and light transmittance of InP.

FIG. 6A is a chart showing a first characteristic example in a case where an optical filter is additionally provided.

FIG. 6B is a chart showing a second characteristic example in a case where an optical filter is additionally provided.

FIG. 7A is a diagram illustrating a planar configuration of a semiconductor wafer.

FIG. 7B is an enlarged view of a region B in FIG. 5A, illustrating a configuration of a chip formation region.

FIG. 8A is a schematic process cross-sectional view illustrating a method for manufacturing the solid-state imaging device according to the first embodiment of the present technology.

FIG. 8B is a schematic process cross-sectional view following FIG. 8A.

FIG. 8C is a schematic process cross-sectional view following FIG. 8B.

FIG. 8D is a schematic process cross-sectional view following FIG. 8C.

FIG. 8E is a schematic process cross-sectional view following FIG. 8D.

FIG. 8F is a schematic process cross-sectional view following FIG. 8E.

FIG. 8G is a schematic process cross-sectional view following FIG. 8F.

FIG. 8H is a schematic process cross-sectional view following FIG. 8G.

FIG. 8I is a schematic process cross-sectional view following FIG. 8H.

FIG. 9A is a schematic plan view illustrating a first modification of the arrangement pattern of the pixel including the first light transmitting part and the pixel including the second light transmitting part.

FIG. 9B is a schematic plan view illustrating a second modification of the arrangement pattern of the pixel including the first light transmitting part and the pixel including the second light transmitting part.

FIG. 9C is a schematic plan view illustrating a third modification of the arrangement pattern of the pixel including the first light transmitting part and the pixel including the second light transmitting part.

FIG. 9D is a schematic plan view illustrating a fourth modification of the arrangement pattern of the pixel including the first light transmitting part and the pixel including the second light transmitting part.

FIG. 10 is a schematic cross-sectional view of a main part illustrating a configuration example of a solid-state imaging device according to a second embodiment of the present technology.

FIG. 11 is a schematic cross-sectional view of a main part illustrating a configuration example of a solid-state imaging device according to a third embodiment of the present technology.

FIG. 12 is a schematic cross-sectional view of a main part illustrating a configuration example of a solid-state imaging device according to a fourth embodiment of the present technology.

FIG. 13 is a schematic cross-sectional view of a main part illustrating a configuration example of a solid-state imaging device according to a fifth embodiment of the present technology.

FIG. 14 is a schematic cross-sectional view of a main part illustrating a configuration example of a solid-state imaging device according to a sixth embodiment of the present technology.

FIG. 15 is a schematic cross-sectional view of a main part illustrating a configuration example of a solid-state imaging device according to a seventh embodiment of the present technology.

FIG. 16A is a schematic cross-sectional view of a main part illustrating a configuration example of a solid-state imaging device according to an eighth embodiment of the present technology.

FIG. 16B is a schematic plan view illustrating an arrangement pattern of a pixel including the first light transmitting part and a color filter and the pixel including the second light transmitting part.

FIG. 16C is a schematic plan view illustrating a modification of the arrangement pattern of the pixel including the first light transmitting part and the pixel including the second light transmitting part.

FIG. 17A is a schematic cross-sectional view of a main part illustrating a configuration example of a solid-state imaging device according to a ninth embodiment of the present technology.

FIG. 17B is a schematic plan view illustrating an arrangement pattern of the pixel including the first light transmitting part, the pixel including the second light transmitting part, and a pixel including a third light transmitting part.

FIG. 17C is a schematic plan view illustrating a modification of the arrangement pattern of the pixel including the first light transmitting part, the pixel including the second light transmitting part, and the pixel including the third light transmitting part.

FIG. 18 is a diagram illustrating a schematic configuration of an electronic device according to a tenth embodiment of the present technology.

### MODE FOR CARRYING OUT THE INVENTION

Hereinafter, embodiments of the present technology will be described in detail with reference to the drawings.

Note that, in all the drawings for describing the embodiments of the present technology, components having the same functions are denoted by the same reference signs, and repeated description thereof will be omitted.

In addition, each drawing is schematic and may be different from an actual one. Furthermore, the following embodiments illustrate a device and a method for embodying the technical idea of the present technology, and do not specify the configuration as follows. That is, various modifications can be made to the technical idea of the present technology within the technical scope described in the claims.

Furthermore, in the following embodiments, in three directions orthogonal to each other in a space, a first direction and a second direction orthogonal to each other in the same plane are defined as an X direction and a Y direction, respectively, and a third direction orthogonal to the first direction and the second direction is defined as a Z direction. In the following embodiments, a thickness direction of a semiconductor layer to be described later will be described as the Z direction.

### First Embodiment

In the first embodiment, an example in which the present technology is applied to a solid-state imaging device that is a back-illuminated complementary metal oxide semiconductor (CMOS) image sensor will be described.

<<Overall Configuration of Solid-State Imaging Device>>

First, an overall configuration of a solid-state imaging device 1A will be described.

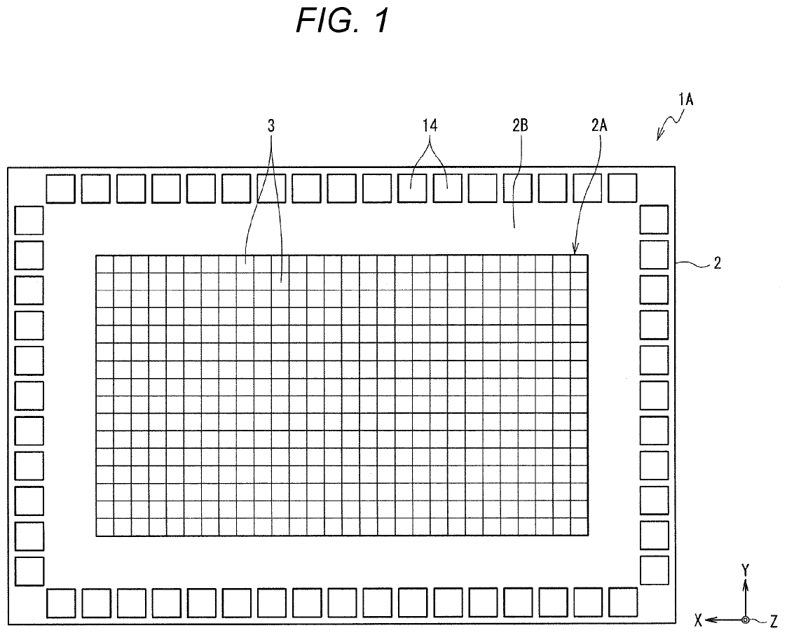

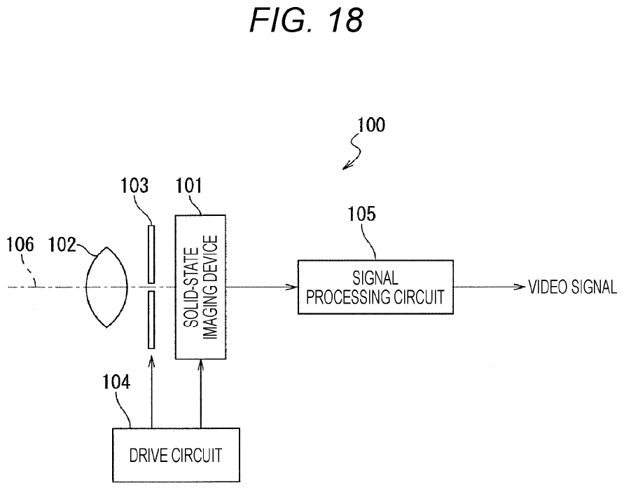

As illustrated in FIG. 1A, the solid-state imaging device 1A according to the first embodiment of the present technology mainly includes a semiconductor chip 2 having a rectangular two-dimensional planar shape in plan view. That is, the solid-state imaging device 1A is mounted on the semiconductor chip 2. As illustrated in FIG. 18, the solid-state imaging device 1A receives image light (incident light 106) from a subject through an optical lens 102, converts an amount of the incident light 106 formed as an image on an imaging surface into an electrical signal for each pixel, and outputs the electrical signal as a pixel signal.

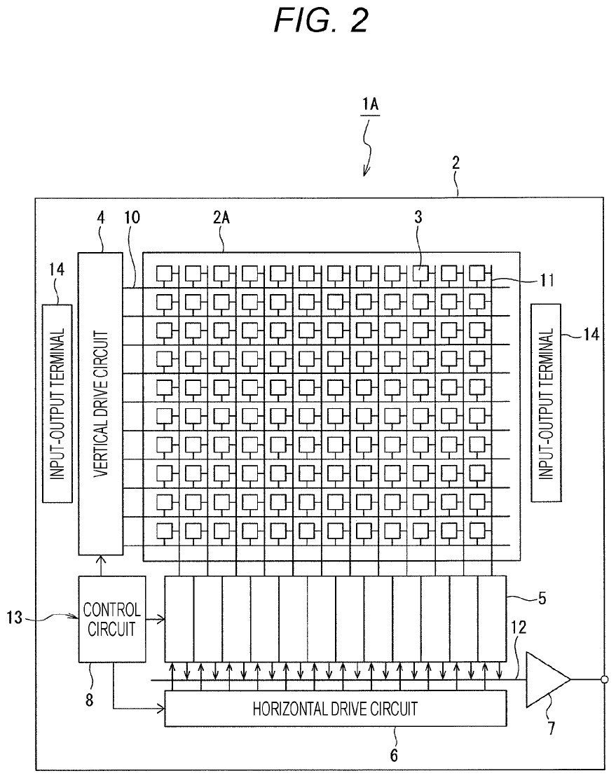

As illustrated in FIGS. 1 and 2, the semiconductor chip 2 on which the solid-state imaging device 1A is mounted includes, in a two-dimensional plane, a rectangular pixel region 2A provided in a central portion, and a peripheral region 2B arranged outside the pixel region 2A so as to surround the pixel region 2A.

The pixel region 2A is, for example, a light receiving surface that receives light condensed by the optical lens (optical system) 102 illustrated in FIG. 18. Then, in the pixel region 2A, a plurality of pixels 3 is arranged in a matrix in a two-dimensional plane including the X direction and the Y direction. In other words, the pixels 3 are repeatedly arranged in each of the X direction and the Y direction orthogonal to each other in the two-dimensional plane.

As illustrated in FIG. 1A, a plurality of bonding pads 14 is arranged in the peripheral region 2B. The plurality of bonding pads 14 is arranged, for example, along four sides in the two-dimensional plane of the semiconductor chip 2. Each of the plurality of bonding pads 14 is an input-output terminal used when the semiconductor chip 2 is electrically connected to an external device.

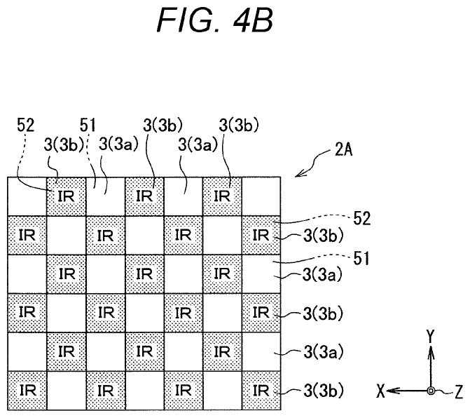

As illustrated in FIG. 4A, the pixel region 2A includes an effective pixel region 2A₁ and an optical black region 2A₂ that is disposed so as to surround the effective pixel region 2A₁ and outputs an optical reference black level. As illustrated in FIG. 4A, the optical black region 2A₂ is covered with a light shielding film 53b to be described later. The plurality of pixels 3 include a pixel 3a and a pixel 3b as a first pixel and a second pixel arranged in the effective pixel region 2A₁, and a pixel 3c as a third pixel arranged in the optical black region 2A₂.

<Logic Circuit>

As illustrated in FIG. 2, the semiconductor chip 2 includes a logic circuit 13 including a vertical drive circuit 4, a column signal processing circuit 5, a horizontal drive circuit 6, an output circuit 7, a control circuit 8, and the like. The logic circuit 13 includes, for example, a complementary MOS (CMOS) circuit including an n-channel conductive metal oxide semiconductor field effect transistor (MOSFET) and a p-channel conductive MOSFET.

The vertical drive circuit 4 includes, for example, a shift register. The vertical drive circuit 4 sequentially selects a desired pixel drive line 10, supplies a pulse for driving the pixel 3 to the selected pixel drive line 10, and drives each pixel 3 row by row. That is, the vertical drive circuit 4 selectively scans each pixel 3 in the pixel region 2A sequentially in a vertical direction row by row, and a pixel signal from the pixel 3 based on a signal charge generated according to the amount of received light by a photoelectric conversion element of each pixel 3 is supplied to the column signal processing circuit 5 through a vertical signal line 11.

The column signal processing circuit 5 is disposed, for example, for each column of the pixels 3 and performs signal processing, such as noise removal, on signals output from the pixels 3 of one row, for each pixel column. For example, the column signal processing circuit 5 performs signal processing such as correlated double sampling (CDS) for removing pixel-specific fixed pattern noise and analog digital (AD) conversion.

The horizontal drive circuit 6 includes, for example, a shift register. The horizontal drive circuit sequentially outputs horizontal scanning pulses to the column signal processing circuits 5 to sequentially select each of the column signal processing circuits 5, and causes each of the column signal processing circuits to output the pixel signal subjected to the signal processing to a horizontal signal line 12.

The output circuit 7 performs signal processing on pixel signals sequentially supplied from each of the column signal processing circuits 5 through the horizontal signal line 12 and outputs the processed signals. As the signal processing, for example, buffering, black level adjustment, column variation correction, various types of digital signal processing, and the like can be used.

The control circuit 8 generates, on the basis of a vertical synchronization signal, a horizontal synchronization signal, and a master clock signal, a clock signal or a control signal in accordance with which the vertical drive circuit 4, the column signal processing circuit 5, the horizontal drive circuit 6, and the like operate. Then, the control circuit 8 outputs the clock signal or control signal thus generated to the vertical drive circuit 4, the column signal processing circuit 5, the horizontal drive circuit 6, and the like.

<Photoelectric Conversion Element and Readout Circuit>

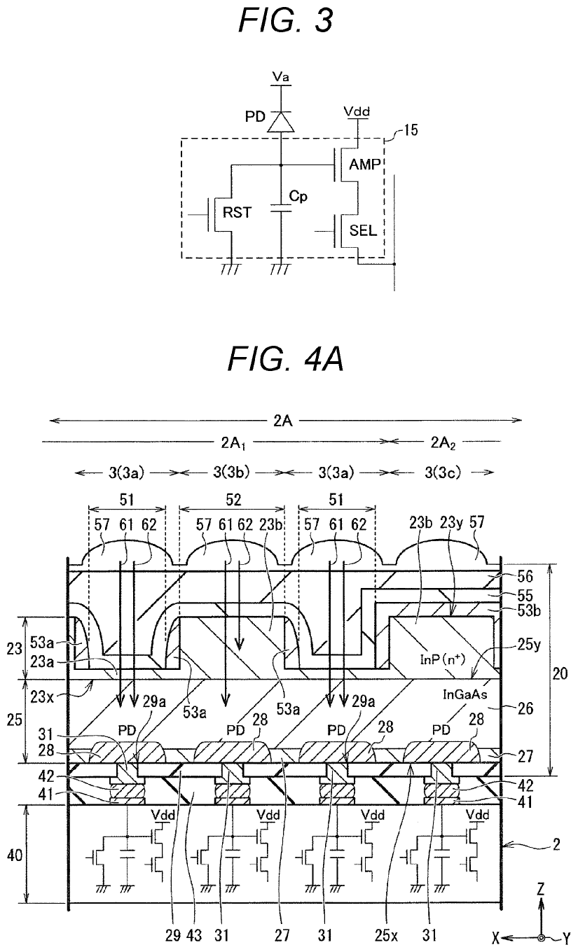

Each pixel 3 of the plurality of pixels includes a photoelectric conversion element PD illustrated in FIG. 3. Then, as illustrated in FIG. 3, a readout circuit 15 is connected to the photoelectric conversion element PD of each pixel 3. Although described in detail later, the photoelectric conversion element PD is contained in a first compound semiconductor layer 25 as illustrated in FIG. 4A, and generates a charge (signal charge) according to the amount of received light. A predetermined bias voltage Va is applied to a cathode side of the photoelectric conversion element PD.

As illustrated in FIG. 3, the readout circuit 15 is connected to an anode side of the photoelectric conversion element PD. The readout circuit 15 includes a capacitive element Cp as a charge accumulation section (charge holding section), a reset transistor RST, an amplification transistor AMP, and a selection transistor SEL. These transistors (RST, AMP, SEL) each include, for example, a MOSFET having a silicon oxide film as a gate insulating film. Alternatively, these transistors (RST, AMP, SEL) may each include a metal insulator semiconductor FET (MISFET) having a silicon nitride (Si₃N₄) film or a stacked film of a silicon nitride film and a silicon oxide film as a gate insulating film.

The capacitive element Cp accumulates signal charges generated by the photoelectric conversion element PD. The capacitive element Cp is constituted by, for example, any one of a pn junction capacitance, a MOS capacitance, and a wiring capacitance.

When being turned on in response to the application of a reset signal to a gate electrode of the reset transistor RST, the reset transistor RST discharges the signal charges accumulated in the capacitive element Cp to reset a potential of the capacitive element Cp.

The amplification transistor AMP outputs a pixel signal corresponding to the storage potential of the capacitive element Cp. Specifically, the amplification transistor AMP constitutes a source follower circuit with a load MOS as a constant current source connected via the vertical signal line 11. The source follower circuit outputs a pixel signal indicating a level corresponding to the signal charges accumulated in the capacitive element Cp from the amplification transistor AMP to the column signal processing circuit 5 via the selection transistor SEL and the vertical signal line 11.

When turned on in response to the application of a selection signal to a gate electrode of the selection transistor SEL, the selection transistor SEL outputs the pixel signal of the pixel 3 to the column signal processing circuit 5 via the vertical signal line 11. A signal line through which the selection signal is transferred and a signal line through which the reset signal is transferred correspond to the pixel drive line 10 in FIG. 2.

<<Specific Configuration of Solid-State Imaging Device>>

Next, a specific configuration of the solid-state imaging device 1A will be described.

As illustrated in FIG. 4A, the semiconductor chip 2 includes a photoelectric conversion substrate part 20 and a circuit substrate part 40 stacked to face each other. The photoelectric conversion substrate part 20 includes the pixel region 2A and the like described above. The circuit substrate part 40 includes the logic circuit 13, the bonding pad 14, the first readout circuit 15, and the like described above.

<Photoelectric Conversion Substrate Part 20>

As illustrated in FIG. 4A, the photoelectric conversion substrate part 20 includes a first compound semiconductor layer 25 having a first surface 25x and a second surface 25y located on opposite sides of the first compound semiconductor layer 25, and a second compound semiconductor layer 23 on the second surface 25y side of the first compound semiconductor layer 25. The first compound semiconductor layer 25 and the second compound semiconductor layer 23 are each provided in common for each pixel 3 (3a, 3b, 3c). Then, in the first compound semiconductor layer 25, the photoelectric conversion element PD described above is provided for each pixel 3.

Here, the first surface 25x of the first compound semiconductor layer 25 may be referred to as an element formation surface or a main surface, and the second surface 25y may be referred to as a light incident surface or a back surface. Furthermore, a first surface 23x and a second surface 23y located on opposite sides of the second compound semiconductor layer 23 are also referred to as a main surface, and a light incident surface or a back surface, respectively.

Furthermore, as illustrated in FIG. 4A, the photoelectric conversion substrate part 20 further includes a protective film 29 disposed on the first surface 25x side of the first compound semiconductor layer 25 to cover the first surface 25x. The protective film 29 is provided in common for each pixel 3 (3a, 3b, 3c). Furthermore, the photoelectric conversion substrate part 20 further includes a light shielding film 53a as a first light shielding film, a light shielding film 53b as a second light shielding film, an antireflection film 55, a planarization film 56, and a microlens (on-chip lens) on the second surface 23y side (light incident surface side) of the second compound semiconductor layer 23.

Furthermore, as illustrated in FIG. 4A, the photoelectric conversion substrate part 20 includes a first light transmitting part 51 that is provided on the light incident surface side, which is the second surface 25y side, of the first compound semiconductor layer 25 and transmits light having a wavelength in the infrared region (infrared light 61) and light having a wavelength in the visible region (visible light 62), and a second light transmitting part 52 that is provided on the second surface 25y side (light incident surface side) of the first compound semiconductor layer 25 and includes the second compound semiconductor layer 23 to transmit the infrared light 61 and blocks the transmission of the visible light 62.

The first compound semiconductor layer 25 includes, for example, a photoelectric conversion layer 26 and a cap layer 27 in this order from the first surface 25x side. Then, the second compound semiconductor layer 23, the photoelectric conversion layer 26 of the first compound semiconductor layer 25, and the cap layer 27 of the first compound semiconductor layer 25 are epitaxial layers epitaxially grown on a growth substrate (not illustrated) in this order. That is, in the first compound semiconductor layer 25, the photoelectric conversion layer 26 and the cap layer 27 are covalently bonded to each other, and further, the photoelectric conversion layer 26 is covalently bonded to the second compound semiconductor layer 23.

The cap layer 27 is provided in common for all the pixels 3, for example, and is disposed between the protective film 29 and the photoelectric conversion layer 26. The cap layer 27 is provided with a plurality of contact regions 28 each including, for example, a semiconductor region (impurity diffusion region). The use of a compound semiconductor material that is wider in band gap (Eg) than the compound semiconductor material constituting the photoelectric conversion layer 26 for the cap layer 27 makes it possible to inhibit dark current. For the cap layer 27, for example, n-type indium phosphide (InP) can be used.

The plurality of contact regions 28 is arranged at intervals and is provided for each pixel 3 on a one-to-one basis. Then, a connection electrode (element-side connection electrode) 31 is individually connected to each contact region 28 through an opening 29a provided in the protective film 29. The contact region 28 is also provided in the optical black region 2A₂.

The contact region 28 is for reading out signal charges generated in the photoelectric conversion layer from each pixel 3, and contains, for example, p-type impurities. Examples of the p-type impurities include zinc (Zn) and the like. In this manner, a pn junction interface is formed between the contact region 28 and the cap layer 27 other than the contact region 28, and the pixels 3 adjacent to each other are electrically isolated. The contact region 28 is formed thicker than the cap layer 27, and is also provided in a part of the photoelectric conversion layer 26 in the thickness direction (Z direction).

The photoelectric conversion layer 26 between the cap layer 27 and the second compound semiconductor layer is provided in common for all the pixels 3 (3a, 3b, 3c), for example. The photoelectric conversion layer 26 absorbs light having a predetermined wavelength, in the first embodiment, infrared light and visible light, to generate signal charges, and the photoelectric conversion layer 26 includes, for example, a group III-V compound semiconductor material containing n-type impurities or an i-type group III-V compound semiconductor material. As the compound semiconductor material constituting the photoelectric conversion layer 26, for example, a compound semiconductor containing any one of indium gallium arsenide (InGaAs), Ex. InGaAs, or an indium gallium antimony (InGaAs/GaAsSb) superlattice can be used. Furthermore, as the compound semiconductor material constituting the photoelectric conversion layer 26, for example, a compound semiconductor containing lattice-mismatched “In_{>0.53}Ga_{>0.47}As” can be used. In the first embodiment, i-type InGaAs is used as the photoelectric conversion layer 26. The photoelectric conversion layer photoelectrically converts light having a wavelength in the infrared region and light having a wavelength in the visible region.

As illustrated in FIG. 4A, the second compound semiconductor layer 23 is covalently bonded to the photoelectric conversion layer 26 of the first compound semiconductor layer 25, and is provided over the effective pixel region 2A₁ and the optical black region 2A₂ of the pixel region 2A in plan view. Then, in the first embodiment, the second compound semiconductor layer is provided in common for all the pixels 3. The second compound semiconductor layer 23 also functions as an electrode in common for each pixel 3, and discharges charges that are not used as signal charges among the charges generated in the photoelectric conversion layer (cathode). For example, in a case where holes are read out from the connection electrode 31 as signal charges, for example, electrons can be discharged through the second compound semiconductor layer 23. The predetermined bias voltage Va is applied to the second compound semiconductor layer 23.

The connection electrode (element-side connection electrode) 31 is an electrode (anode) to which a voltage for reading out signal charges (holes or electrons, hereinafter, for convenience, the description will be made on the assumption that the signal charges are holes) generated in the photoelectric conversion layer 26 is supplied, and is provided in the pixel region 2A for each pixel 3. That is, the photoelectric conversion element PD including the connection electrode 31, the photoelectric conversion layer 26, and the second compound semiconductor layer 23 also functioning as an electrode is provided for each pixel 3. Then, the connection electrode 31 functions as an anode-side electrode of the photoelectric conversion element PD, and the second compound semiconductor layer 23 functions as a cathode-side electrode of the photoelectric conversion element PD.

The connection electrode 31 includes, for example, any one of titanium (Ti), tungsten (W), titanium nitride (TiN), platinum (Pt), gold (Au), germanium (Ge), palladium (Pd), zinc (Zn), nickel (Ni), or aluminum (Al), or an alloy containing at least one of them. The connection electrode 31 may be a single film of such a constituent material, or may be a stacked film obtained by combining two or more of the constituent materials. For example, the connection electrode 31 includes a stacked film of titanium and tungsten, and has a film thickness of about several tens nm to several hundreds nm.

As illustrated in FIG. 4A, the protective film 29 is provided between the first compound semiconductor layer 25 and an insulating layer 43. The protective film includes, for example, an oxide such as silicon oxide (SiOx) or aluminum oxide (Al₂O₃). The protective film 29 may have a stacked structure in which a plurality of films is stacked. The protective film 29 may include, for example, a silicon (Si) insulating material such as silicon oxynitride (SiON), carbon-containing silicon oxide (SiOC), silicon nitride (SiN), and silicon carbide (SiC). The thickness of the protective film 29 is, for example, about several tens nm to several hundreds nm.

As illustrated in FIG. 4A, the second compound semiconductor layer 23 includes a first portion 23a formed with such a thickness (film thickness) as to transmit the infrared light 61 and the visible light 62, and a second portion 23b formed with such a thickness (film thickness) as to transmit the infrared light 61 and block the transmission of the visible light 62, and the first portion 23a is thinner than the second portion 23b. The second compound semiconductor layer 23 includes a compound semiconductor wider in band gap (Eg) than the photoelectric conversion layer 26 of the first compound semiconductor layer 25. Then, the second compound semiconductor layer 23 includes an n-type compound semiconductor that is highly doped as compared to the photoelectric conversion layer 26 of the first compound semiconductor layer 25, and also functions as an electrode as described above.

As the material of the second compound semiconductor layer 23, a compound semiconductor containing any one of InGaAs, GaAsSb, InGaAsP, InGaAlAs, InP, InAlAs, InAlAsSb, AlAsSb, AlAsSb, InAsP, or InSbP can be used. In the first embodiment, InP containing n-type impurities is used as the compound semiconductor material constituting the second compound semiconductor layer 23. The second compound semiconductor layer 23 and the first compound semiconductor layer 25 described above include different compound semiconductor materials.

(Film Thickness and Light Transmittance of InP)

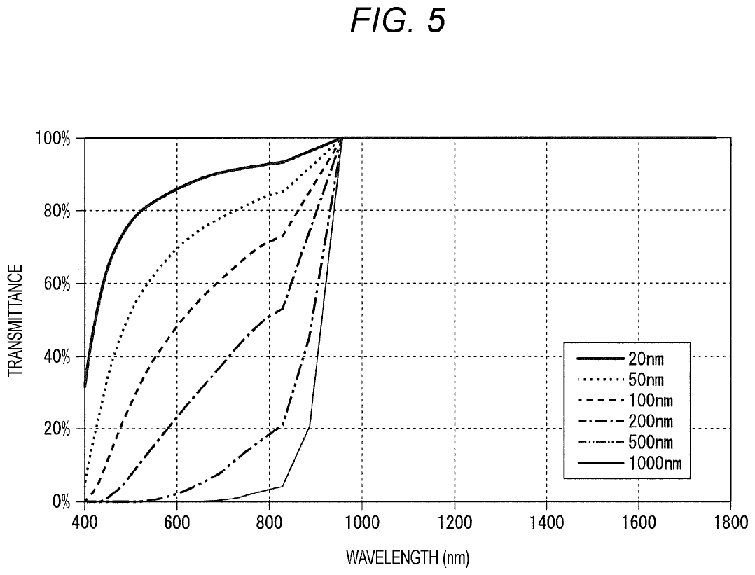

FIG. 5 is a characteristic chart showing dependency on a film thickness and light transmittance of InP. FIG. shows cases where the film thickness of InP is 20 nm, nm, 100 nm, 200 nm, 500 nm, and 1000 nm. The wavelength range of infrared light is approximately from nm to 1 mm. The wavelength range of visible light is approximately from a lower limit of 360 nm to 400 nm to an upper limit of 760 nm to 830 nm.

As shown in FIG. 5, when the wavelength band of light is approximately less than or equal to 950 nm, the light transmittance depends on the film thickness, the light transmittance increases as the film thickness decreases, and the transmittance decreases as the film thickness increases. It is therefore possible to form, in the second compound semiconductor layer 23 containing n-type InP, the first portion 23a that transmits the infrared light 61 and the visible light 62 and the second portion 23b that transmits the infrared light 61 and blocks the transmission of the visible light 62 by partially changing the film thickness. The first portion 23a is smaller in film thickness than the second portion 23b. In the first embodiment, in the second compound semiconductor layer 23, the film thickness of the first portion 23a is set at, for example, about several tens nm, and the film thickness of the second portion 23b is set at, for example, about 1000 nm.

(Pixel and Light Transmitting Part)

As illustrated in FIG. 4A, the pixel 3a in the effective pixel region 2A₁ includes the first light transmitting part 51 that is provided on the second surface 25y side (light incident surface side) of the first compound semiconductor layer 25 and includes the first portion 23a of the second compound semiconductor layer 23 that transmits the infrared light 61 and the visible light 62, and the photoelectric conversion element PD as a first photoelectric conversion element that is provided in the first compound semiconductor layer 25 and photoelectrically converts the infrared light 61 and the visible light 62 that have passed through the first light transmitting part 51. Then, the first light transmitting part 51 and the photoelectric conversion element PD of the pixel 3a are aligned with each other in plan view.

As illustrated in FIG. 4A, the pixel 3b in the effective pixel region 2A₁ includes the second light transmitting part 52 that is provided on the second surface 25y side of the first compound semiconductor layer 25 and includes the second portion 23b of the second compound semiconductor layer 23 that transmits the infrared light 61 and blocks the transmission of the visible light 62, and the photoelectric conversion element PD as a second photoelectric conversion element that is provided in the first compound semiconductor layer 25 and photoelectrically converts the infrared light 61 that has passed through the second light transmitting part 52. Then, the second light transmitting part 52 and the photoelectric conversion element PD of the pixel 3b are aligned with each other in plan view.

As illustrated in FIG. 4A, the pixel 3c in the optical black region 2A₂ includes the second portion 23b of the second compound semiconductor layer 23 provided on the second surface 25y side of the first compound semiconductor layer 25, the light shielding film 53b covering upper and side surfaces of the second portion 23b, and the photoelectric conversion element PD as a third photoelectric conversion element provided in the first compound semiconductor layer 25 in alignment with the second portion 23b in plan view. In the pixel 3c, the second portion 23b of the second compound semiconductor layer 23 is covered with the light shielding film 53b, so that photoelectric conversion by the photoelectric conversion element PD is basically not performed.

As illustrated in FIG. 4B, the pixel 3a including the first light transmitting part 51 and the pixel 3b including the second light transmitting part 52 are alternately and repeatedly arranged in each of the X direction and the Y direction orthogonal to each other in plan view. That is, in the pixel region 2A of the first embodiment, the pixel 3a including the first light transmitting part 51 and the pixel 3b including the second light transmitting part 52 are arranged in a checkered planar arrangement pattern (checkered pattern) in which the pixel 3a and the pixel 3b are alternately and repeatedly arranged in each of the X direction and the Y direction in plan view.

<Other Configurations>

As illustrated in FIG. 4A, the light shielding film 53a is provided on the side surface (side wall) of the second portion 23b of the second compound semiconductor layer 23 in the pixel 3b so as to surround the second portion 23b in plan view, and is formed in self-alignment with the second portion 23b. The light shielding film 53a is provided for each pixel 3b, and prevents light from leaking from a predetermined pixel 3 to an adjacent pixel 3 in the effective pixel region 2A₁.

As illustrated in FIG. 4A, the light shielding film 53b is provided to cover the upper and side surfaces of the second portion 23b of the second compound semiconductor layer 23 in the pixel 3c. The light shielding film 53b is provided for each pixel 3c, and prevents light incident from the light incident surface side of the semiconductor chip 2 from passing through the second portion 23b of the second compound semiconductor layer 23 in the pixel 3c and impinging on the photoelectric conversion layer 26 (photoelectric conversion element PD) in the optical black region 2A₂. The light shielding film 53b and the light shielding film 53a described above are formed in the same process, and each include, for example, a stacked film of titanium (Ti) and tungsten (W).

As illustrated in FIG. 4A, the antireflection film is provided on the second surface 23y side of the second compound semiconductor layer 23 over the effective pixel region 2A₁ and the optical black region 2A₂ of the pixel region 2A in plan view so as to cover the first portion 23a and the second portion 23b of the second compound semiconductor layer 23, and the light shielding film 53a and the light shielding film 53b. As a material of the antireflection film 55, for example, silicon nitride (SiN), hafnium oxide (HfO₂), aluminum oxide (Al₂O₃), zirconium oxide (ZrO₂), tantalum oxide (Ta₂O₅), titanium oxide (TiO₂), or the like that can transmit infrared light and visible light can be used.

As illustrated in FIG. 4A, the planarization film is provided on the second surface 23y side of the second compound semiconductor layer 23 over the effective pixel region 2A₁ and the optical black region 2A₂ of the pixel region 2A in plan view so as to cover the antireflection film 55. The planarization film 56 fills a step generated due to a difference in thickness between the first portion 23a and the second portion 23b of the second compound semiconductor layer 23, and covers all of a light reflection surface side (second surface 23y side) of the second compound semiconductor layer 23 so as to make the second surface 23y side (light incident surface side) of the second compound semiconductor layer 23 flat without unevenness. As the planarization film 56, for example, a resin-based insulating material that can transmit the infrared light 61 and the visible light 62 and is excellent in embeddability can be used.

That is, in the first embodiment, the first light transmitting part 51 includes the first portion 23a of the second compound semiconductor layer 23, and further includes the antireflection film 55 and the planarization film 56 that transmit the infrared light 61 and the visible light 62. Furthermore, the second light transmitting part 52 includes the second portion 23b of the second compound semiconductor layer 23, and further includes the antireflection film 55 and the planarization film 56 that transmit the infrared light 61 and the visible light 62.

As illustrated in FIG. 4A, the microlens 57 is provided on the light incident surface side of the planarization film 56 remote from the second compound semiconductor layer 23. The microlens 57 is provided for each pixel 3 in the pixel region 2A, and is arranged in a matrix corresponding to the arrangement of the plurality of pixels 3. The microlens 57 condenses irradiation light and allows the condensed light to efficiently enter the pixel 3. The microlens 57 includes, for example, a resin material.

<Circuit Substrate Part 40>

Although no specific configuration is illustrated in FIG. 4A, the circuit substrate part 40 includes a semiconductor substrate including, for example, single crystal silicon, and a multilayer wiring layer disposed on a first surface side of the semiconductor substrate opposite from a second surface of the semiconductor substrate in the thickness direction (Z direction). The semiconductor substrate of the circuit substrate part 40 is provided with an active element and a passive element included in circuits such as the logic circuit 13 and the readout circuit 15 described above. In FIG. 4A, the readout circuit 15 illustrated in FIG. 3 is illustrated without the reference signs.

As illustrated in FIG. 4A, a connection electrode 41 is provided in an uppermost wiring layer of the circuit substrate part 40. The connection electrode 41 is disposed corresponding to the connection electrode 31 of the photoelectric conversion substrate part 20. Then, the connection electrode 41 is electrically connected to the readout circuit 15.

As illustrated in FIG. 4A, the connection electrode of the circuit substrate part 40 is electrically and mechanically connected to the connection electrode 31 of the photoelectric conversion substrate part 20 via a bump electrode 42. Then, the insulating layer 43 is provided in a space between the circuit substrate part 40 and the photoelectric conversion substrate part 20 except for the bump electrode 42. The circuit substrate part 40 and the photoelectric conversion substrate part 20 are joined together by the bump electrode 42 and the insulating layer 43. The photoelectric conversion element PD of the circuit substrate part 40 has the anode side electrically connected to the readout circuit 15 via the connection electrode 31, the bump electrode 42, and the connection electrode 41.

<<Method for Manufacturing Solid-State Imaging Device>>

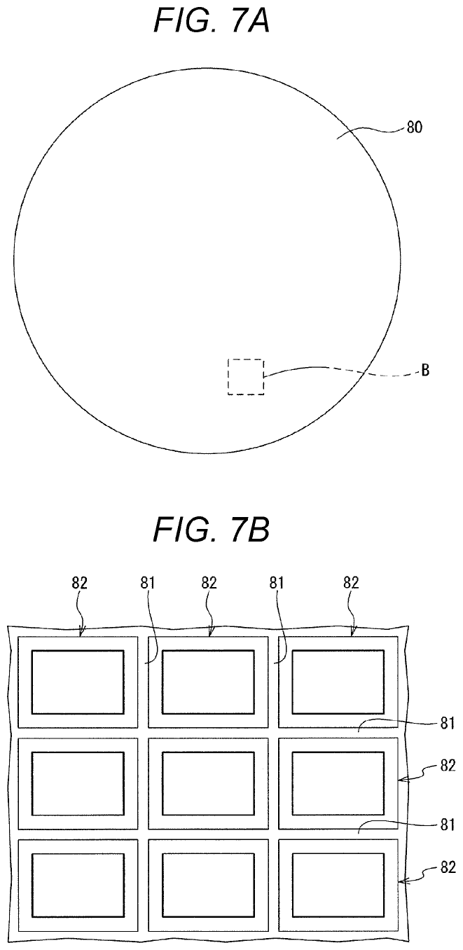

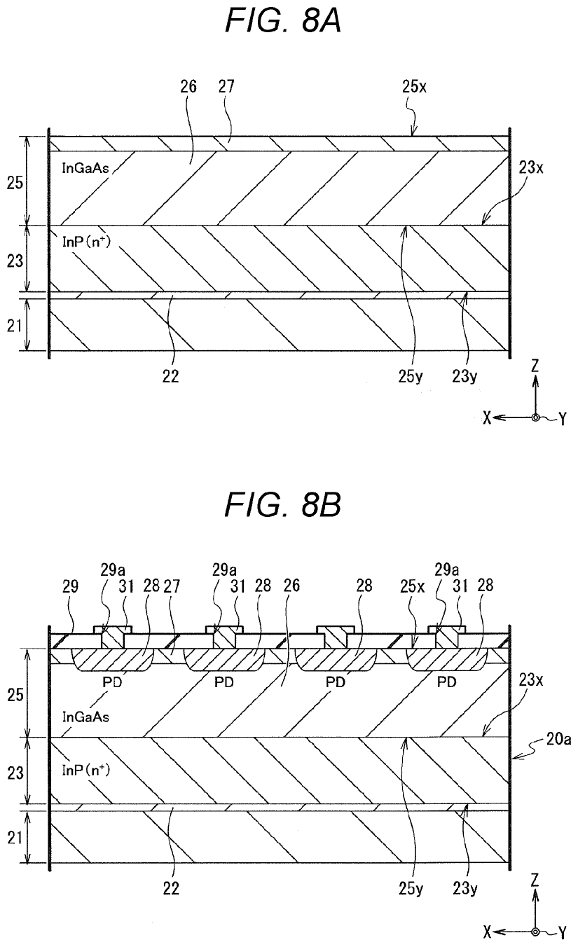

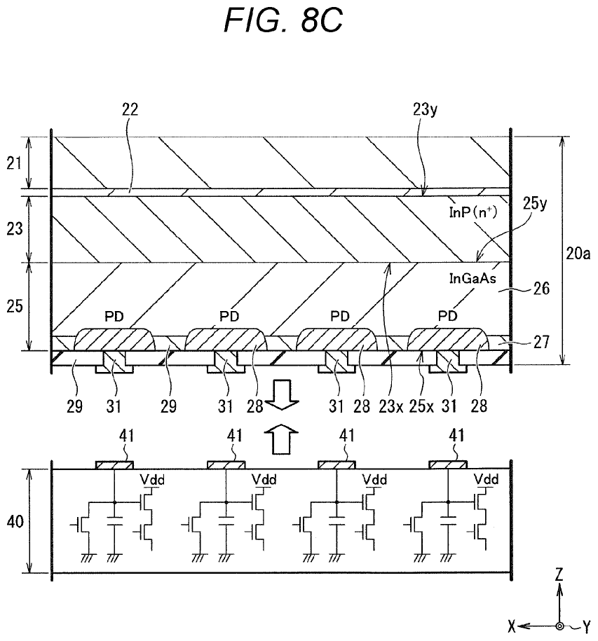

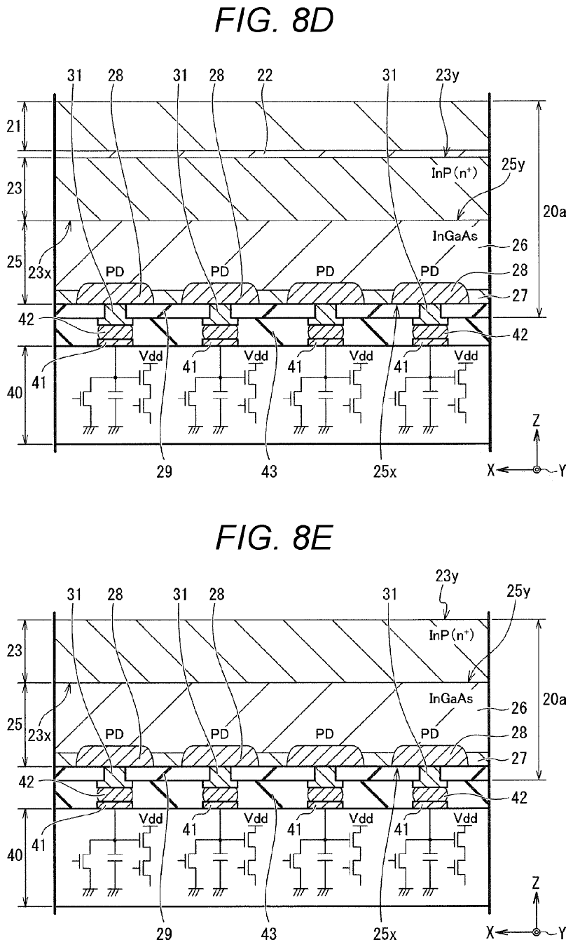

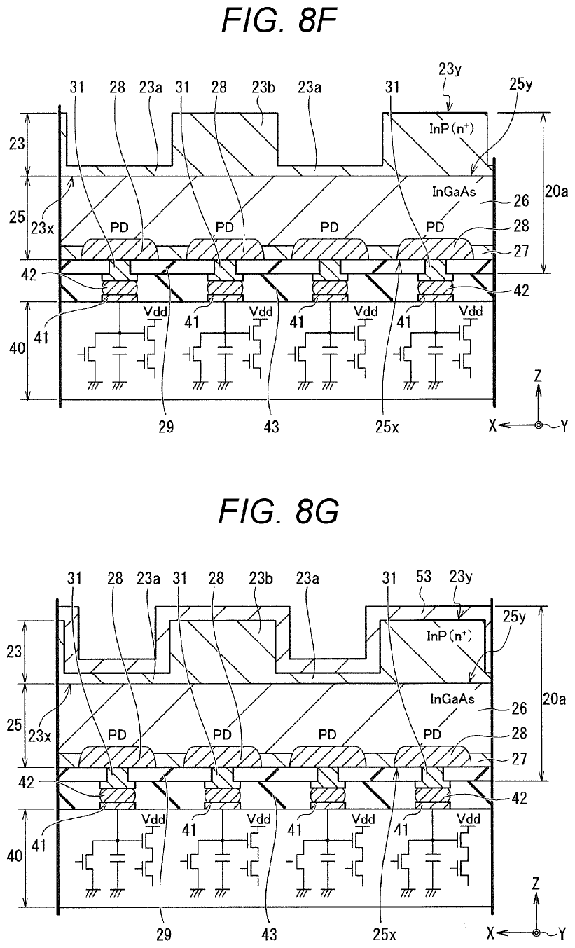

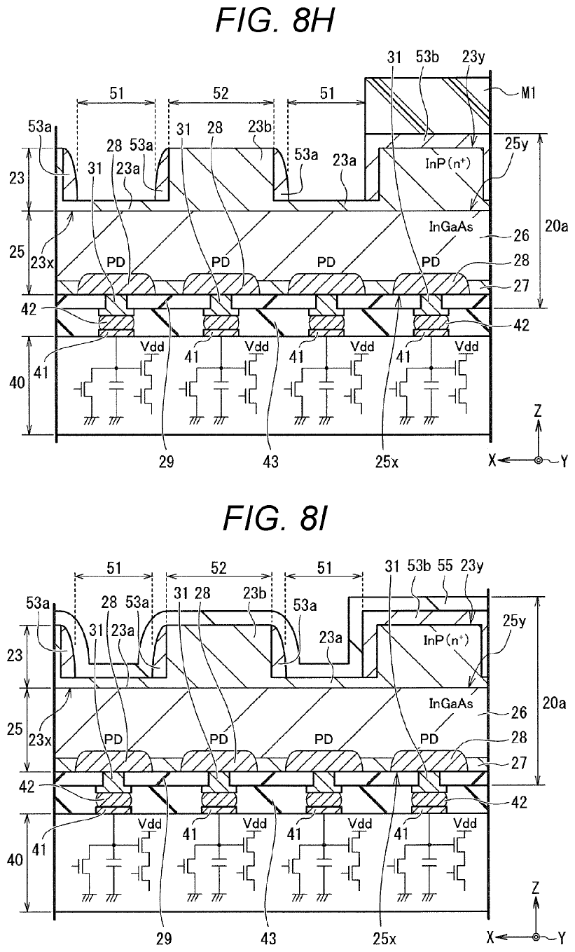

Next, a method for manufacturing the solid-state imaging device 1A according to the first embodiment will be described with reference to FIGS. 7A and 7B and FIGS. 8A to 8I.

FIG. 7A is a diagram illustrating a planar configuration of a semiconductor wafer, and FIG. 7B is an enlarged view of a region B in FIG. 7A, illustrating a configuration of a chip formation region.

Furthermore, FIGS. 7A to 7J are schematic cross-sectional views for describing the method for manufacturing the solid-state imaging device 1A.

Here, as illustrated in FIGS. 7A and 7B, the solid-state imaging device 1A is manufactured in a chip formation region 82 of a semiconductor wafer 80. The chip formation region 82 is partitioned by scribe lines 81, and a plurality of chip forming regions is arranged in a matrix. In FIG. 7B, nine chip formation regions 82 arranged in a three-by-three matrix in the X direction and the Y direction are illustrated. Then, the plurality of chip formation regions 82 is separated, along the scribe lines 81, into single chips to thereby form the semiconductor chip 2 on which the solid-state imaging device 1A is mounted. The chip formation regions 82 are separated into single chips after the solid-state imaging device 1A is formed in each chip formation region 82 by a manufacturing process to be described below.

Note that the scribe lines 81 are not physically formed.

The method for manufacturing the solid-state imaging device 1A according to the first embodiment includes a process of forming a photoelectric conversion substrate part 20a illustrated in FIG. 8C and a process of forming the circuit substrate part 40 illustrated in FIG. 8C. Either the photoelectric conversion substrate part 20a or the circuit substrate part 40 may be formed first, or the photoelectric conversion substrate part 20a and the circuit substrate part 40 may be formed at a time. In the first embodiment, the formation of the photoelectric conversion substrate part 20a will be described first, but the order of forming the photoelectric conversion substrate part 20a and the circuit substrate part 40 is not limited to the first embodiment.

First, as illustrated in FIG. 8A, an etching stopper layer 22 containing, for example, InGaAs as a compound semiconductor material, the second compound semiconductor layer 23 containing, for example, n-type InP as a compound semiconductor material, and the first compound semiconductor layer 25 containing a compound semiconductor material are epitaxially grown in this order on a growth substrate 21 containing, for example, InP as a compound semiconductor material. The photoelectric conversion layer 26 containing, for example, i-type InGaAs as a compound semiconductor material and the cap layer 27 containing, for example, n-type InP as a compound semiconductor material are epitaxially grown in this order on, for example, the second compound semiconductor layer 23 to form the first compound semiconductor layer 25. The thickness of the growth substrate 21 is, for example, several hundreds μm, and the thickness of the photoelectric conversion layer 26 is, for example, several μm. As the growth substrate 21, for example, one equal in size to the semiconductor wafer 80 illustrated in FIG. 7A is used. A surface of the first compound semiconductor layer 25 on the cap layer 27 side is the first surface 25x, and a surface opposite to the first surface 25x is the second surface 25y. A surface of the second compound semiconductor layer 23 on the first compound semiconductor layer 25 side is the first surface 23x, and a surface on the etching stopper layer side is the second surface 23y. Then, the second compound semiconductor layer 23 is formed with such a thickness as to transmit infrared light and block the transmission of visible light, for example, a thickness of about 1 μm. The etching stopper layer 22 includes a material having etching selectivity against the growth substrate 21 and the second compound semiconductor layer 23. InGaAs (etching stopper layer 22) has selectivity against InP (growth substrate 21, second compound semiconductor layer 23).

Next, after the first compound semiconductor layer 25 is formed, as illustrated in FIG. 8B, the contact region 28 is formed in a surface layer portion on the first surface 25x side of the first compound semiconductor layer 25. It is possible to form the contact region 28 by selectively ion-implanting impurities into the surface layer portion on the first surface 25x side of the first compound semiconductor layer 25 and then performing heat treatment for activating the ion-implanted impurities. The contact region 28 is preferably formed with such a depth as to protrude from the cap layer 27 toward the photoelectric conversion layer 26. The contact region 28 is formed for each pixel 3.

Next, after the contact region 28 is formed, as illustrated in FIG. 8B, the protective film 29 is formed all over the first surface 25x of the first compound semiconductor layer 25 to cover the first surface 25x. For example, a silicon oxide film is deposited by a chemical vapor deposition (CVD) method to form the protective film 29. The protective film 29 is formed over the effective pixel region 2A₁ and the optical black region 2A₂ of the pixel region 2A.

Next, as illustrated in FIG. 8B, the opening 29a is selectively formed in the protective film 29 on the contact region 28, and subsequently, the connection electrode (element-side connection electrode) 31 that is electrically connected to the contact region 28 is formed through the opening 29a. The opening 29a is formed using a known photolithography technique and etching technique. The opening 29a is formed for each contact region 28. It is possible to form the connection electrode 31 by depositing a conductive film all over the protective film including the inside of the opening 29a of the protective film 29 and then patterning the conductive film. As the conductive film, for example, a conductive film formed by a stacked film of titanium and tungsten and having a film thickness of about several tens nm to several hundreds nm can be used.

In this process, the photoelectric conversion element PD including the connection electrode 31, the photoelectric conversion layer 26, and the second compound semiconductor layer 23 functioning as an electrode is formed for each pixel 3.

Furthermore, In this process, the photoelectric conversion substrate part 20a including the growth substrate 21, the first compound semiconductor layer 25, the second compound semiconductor layer 23, the photoelectric conversion element PD, the protective film 29, and the like is formed.

Next, manufacturing of the circuit substrate part will be described with reference to FIG. 8C.

Although not illustrated in detail, the manufacturing of the circuit substrate part 40 illustrated in FIG. 8C includes a process of forming a transistor included in the above-described logic circuit 13, an active element (AMP1, SEL1, TST1) and a passive element (Cp) included in the above-described readout circuit 15, and the like on the first surface side of the semiconductor substrate. Furthermore, the manufacturing of the circuit substrate part 40 includes a process of forming the multilayer wiring layer on the first surface of the semiconductor substrate. The multilayer wiring layer includes a plurality of the connection electrodes (circuit-side connection electrodes) 41 arranged corresponding to the connection electrodes 31 of the photoelectric conversion substrate part 20 in the uppermost wiring layer.

Next, as illustrated in FIG. 8D, the circuit substrate part 40 and the photoelectric conversion substrate part 20 are bonded together. The circuit substrate part 40 and the photoelectric conversion substrate part 20 are bonded together by melting the bump electrode 42 with the bump electrode 42 interposed between the connection electrode 41 of the circuit substrate part 40 and the connection electrode 31 of the photoelectric conversion substrate part 20 to electrically and mechanically connect the connection electrode 41 and the connection electrode 31, and subsequently forming the insulating layer 43 in the space between the circuit substrate part 40 and the photoelectric conversion substrate part 20 except for the bump electrode 42. It is possible to form the insulating layer 43, for example, by filling the space between the circuit substrate part 40 and the photoelectric conversion substrate part 20 with a thermosetting insulating resin, and then performing heat treatment to cure the thermosetting insulating resin.

Next, after the circuit substrate part 40 and the photoelectric conversion substrate part 20 are bonded together, as illustrated in FIG. 8E, the growth substrate and the etching stopper layer 22 are removed. The growth substrate 21 can be removed by mechanical grinding, CMP, wet etching, dry etching, or the like. The etching stopper layer 22 is removed by wet etching or dry etching under a condition that an etching ratio can be balanced between the etching stopper layer 22 and the second compound semiconductor layer 23. The etching stopper layer 22 is preferably removed by wet etching that causes less damage to the surface of the second compound semiconductor layer 23.

In this process, the etching stopper layer 22 can prevent the surface layer portion of the second compound semiconductor layer 23 from being removed due to over-cutting or over-etching when the growth substrate 21 is removed, so that the thickness of the second compound semiconductor layer 23 can be maintained with high accuracy.

Next, after the growth substrate 21 and the etching stopper layer 22 are removed, as illustrated in FIG. 8F, a predetermined portion of the second compound semiconductor layer 23 is selectively etched to be thinner, so that the first portion 23a is selectively formed, and the second portion 23b is selectively formed in the non-etched portion of the second compound semiconductor layer 23. The first portion 23a is formed at a position where the first portion 23a aligns with the photoelectric conversion element PD constituting the pixel 3a in plan view. The second portion 23b is formed at positions corresponding to the photoelectric conversion element PD constituting the pixel 3b and the photoelectric conversion element PD constituting the pixel 3c. The first portion 23a and the second portion 23b can be formed using a known photolithography technique and etching technique.

The first portion 23a is formed with such a thickness as to transmit infrared light and visible light, for example, a thickness of about several tens nm. The second portion 23b has a thickness approximately equal to the thickness at the time of deposition of the second compound semiconductor layer 23. That is, the second portion 23b is formed with such a thickness (for example, nm) as to transmit infrared light and block the transmission of visible light.

Next, after the first portion 23a and the second portion 23b are formed in the second compound semiconductor layer 23, as illustrated in FIG. 8H, the light shielding film 53a is formed in a sidewall shape on the side surface of the second portion 23b in the pixel 3b among the second portions 23b of the second compound semiconductor layer 23, and light shielding film 53b is formed to cover the upper and side surfaces of the second portion 23b in the pixel 3c among the second portions 23b of the second compound semiconductor layer 23. As illustrated in FIG. 8G, it is possible to form the light shielding films 53a and 53b by forming a light shielding film 53 all over the second compound semiconductor layer including each surface of the first portion 23a and the second portion 23b to cover the second compound semiconductor layer 23, subsequently forming an etching mask Ml on the second portion 23b in the pixel 3c among the second portions 23b of the second compound semiconductor layer 23 with the light shielding film 53 interposed between the etching mask Ml and the second portion 23b by a known photolithography technique, and subsequently performing anisotropic etching such as reactive ion etching (RIE) on the light shielding film 53 using the etching mask Ml as a mask. As the light shielding film 53, for example, a stacked film of titanium (Ti) and tungsten (W) can be used.

In this process, on the light incident surface side (second surface 25y side) of the first compound semiconductor layer 25, the first light transmitting part including the first portion 23a of the second compound semiconductor layer 23 and defined by the light shielding film 53a is formed, and the second light transmitting part 52 including the second portion 23b of the second compound semiconductor layer 23 and defined by the light shielding film 53a is formed.

Next, after the etching mask Ml is removed, as illustrated in FIG. 8I, the antireflection film 55 is deposited on the second surface 23y side of the second compound semiconductor layer 23 by, for example, a CVD method so as to cover the first portion 23a and the second portion 23b of the second compound semiconductor layer 23, and the light shielding film 53a and the light shielding film 53b. The antireflection film 55 is formed over the effective pixel region 2A₁ and the optical black region 2A₂ of the pixel region 2A.

Next, with reference to FIG. 4A, the planarization film 56 is formed on the second surface 23y side of the second compound semiconductor layer 23 by, for example, a spin coating method so as to cover the antireflection film 55, and subsequently, the microlens 57 is formed on the light incident surface side of the planarization film remote from the second compound semiconductor layer 23 for each pixel 3. The planarization film 56 is formed over the effective pixel region 2A₁ and the optical black region 2A₂ of the pixel region 2A.

In this process, the photoelectric conversion substrate part 20 including the growth substrate 21, the first compound semiconductor layer 25, the second compound semiconductor layer 23, the photoelectric conversion element PD, the protective film 29, and the like, and further including the first portion 23a and the second portion 23b of the second compound semiconductor layer 23, the first light transmitting part 51 and the second light transmitting part 52, the light shielding films 53a and 53b, the antireflection film 55, the planarization film 56, the microlens 57, and the like is formed.

Furthermore, In this process, the solid-state imaging device 1A including the photoelectric conversion substrate part 20 and the circuit substrate part 40 is almost completed.

Furthermore, in this process, the semiconductor wafer 80 illustrated in FIGS. 7A and 7B is almost completed. The solid-state imaging device 1A is formed in each chip formation region 82 of the semiconductor wafer 80.

Thereafter, the plurality of chip formation regions of the semiconductor wafer 80 is separated, along the scribe lines 81, into single chips to thereby form the semiconductor chip 2 on which the solid-state imaging device 1A is mounted.

### Effects of First Embodiment

Next, main effects of the first embodiment will be described.

As described above, the solid-state imaging device 1A according to the first embodiment includes the pixel 3a including the first light transmitting part 51 that transmits the infrared light 61 and the visible light 62, and the photoelectric conversion element PD that photoelectrically converts the infrared light 61 and the visible light 62 that have passed through the first light transmitting part 51. Then, the solid-state imaging device 1A according to the first embodiment includes the pixel 3b including the second light transmitting part 52 that transmits the infrared light 61 and blocks the transmission of the visible light 62, and the photoelectric conversion element PD that photoelectrically converts the infrared light 61 that has passed through the second light transmitting part 52. Then, in the pixel 3a, a pixel signal generated by photoelectrically converting the infrared light 61 and the visible light 62 is obtained, and in the pixel 3b, a pixel signal generated by photoelectrically converting the infrared light 61 is obtained. Then, a pixel signal of the visible light 62 is obtained by removing (subtracting) the pixel signal (infrared light 61) of the pixel 3b from the pixel signal (infrared light 61+visible light 62) of the pixel 3a. Therefore, with the solid-state imaging device 1A according to the first embodiment, it is possible to obtain the pixel signal for the two wavelengths of the infrared light 61 and the visible light 62 with one device at a time.

Furthermore, as described above, with the solid-state imaging device 1A according to the first embodiment, it is possible to form, with ease, the first light transmitting part 51 that transmits the infrared light 61 and the visible light 62 and the second light transmitting part 52 that transmits the infrared light 61 and blocks the transmission of the visible light 62 by partially changing the thickness of the second compound semiconductor layer 23. Therefore, with the solid-state imaging device 1A according to the first embodiment, it is possible to obtain the pixel signal for the two wavelengths of the infrared light 61 and the visible light 62 at low cost while suppressing an increase in size of the device.

Furthermore, as described above, the solid-state imaging device 1A according to the first embodiment has a configuration in which the first light transmitting part and the second light transmitting part 52 each include the second compound semiconductor layer 23 that also functions as an electrode in common for each pixel 3 (3a, 3b, 3c). Therefore, with the solid-state imaging device 1A according to the first embodiment, it is possible to stably apply the predetermined bias voltage Va to the cathode side of the photoelectric conversion element PD included in each pixel 3.

Furthermore, under the manufacturing method of the first embodiment, when the growth substrate 21 is removed by mechanical grinding, CMP, wet etching, dry etching, or the like after the etching stopper layer 22, the second compound semiconductor layer 23, and the first compound semiconductor layer 25 are epitaxially grown and formed in this order on the growth substrate 21, the etching stopper layer 22 can prevent the surface layer portion of the second compound semiconductor layer 23 from being removed due to over-cutting or over-etching of the growth substrate 21, so that the thickness of the second compound semiconductor layer 23 can be maintained with high accuracy.

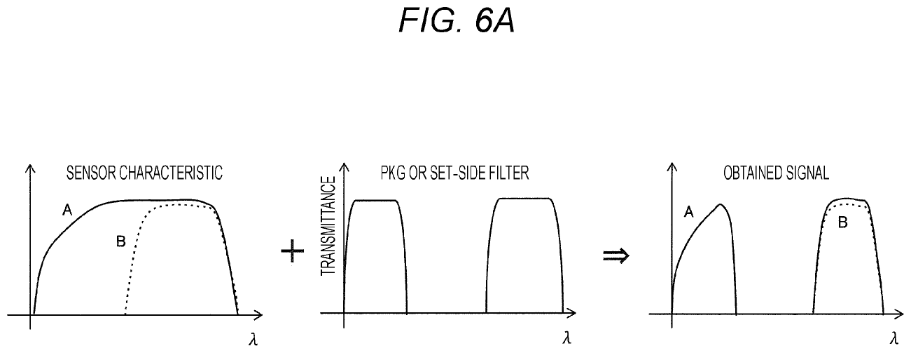

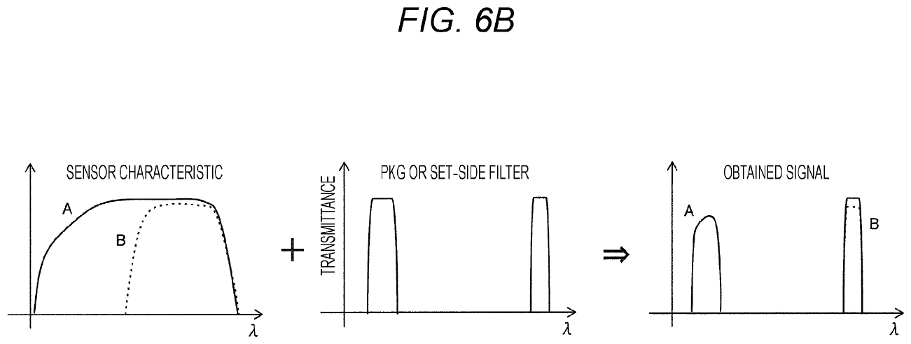

Furthermore, as shown in FIGS. 6A and 6B, the use of a bandpass filter that transmits two wavelengths of visible light and infrared (IR) light on the light incident side of the solid-state imaging device 1A according to the first embodiment, for example, on a PKG glass or a set optical system allows any visible light wavelength and IR wavelength set by the bandpass filter to be extracted.

Furthermore, changing a bandpass width of the bandpass filter allows a wavelength of any bandpass width to be extracted.

### Modification

In the first embodiment described above, as the planar arrangement pattern of the pixel 3a including the first light transmitting part 51 and the pixel 3b(IR) including the second light transmitting part 52 in the pixel region 2A, the checkered planar arrangement pattern in which the pixel 3a including the first light transmitting part 51 and the pixel 3b including the second light transmitting part 52 are alternately and repeatedly arranged in each of the X direction and the Y direction has been described. The present technology, however, is not limited to the checkered planar arrangement pattern described above.

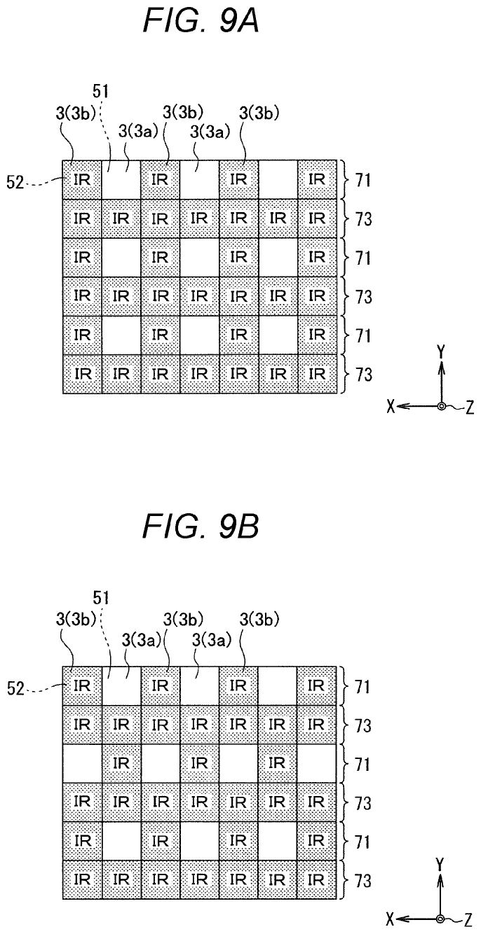

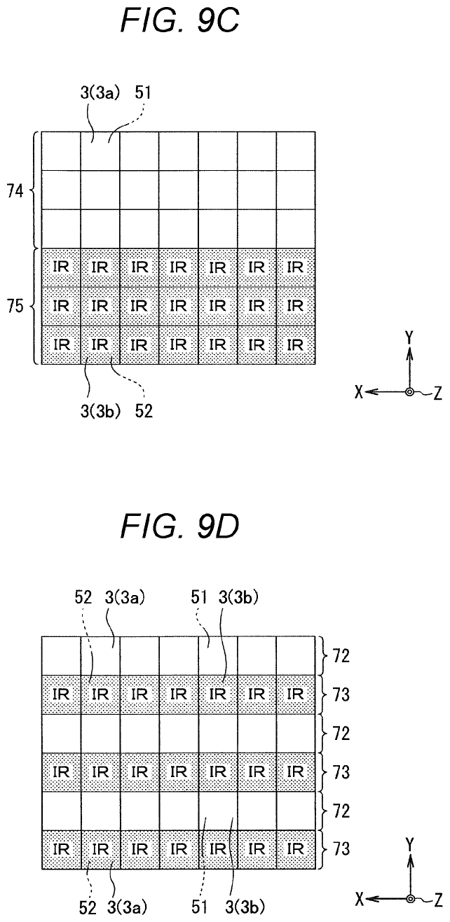

For example, as a first modification, as illustrated in FIG. 9A, the pixel 3a and the pixel 3b(IR) may be arranged in a dot-shaped planar arrangement pattern in which a first pixel column 71 in which the pixel 3a and the pixel 3b are alternately and repeatedly arranged in the X direction and a second pixel column 73 in which the pixel 3b is repeatedly arranged in the X direction with no gap are alternately and repeatedly arranged in the Y direction such that the pixel 3a in the first pixel column 71 and the pixel 3b in the second pixel column 73 are alternately arranged in the Y direction.

Furthermore, as a second modification, as illustrated in FIG. 9B, the pixel 3a and the pixel 3b(IR) may be arranged in a dot-shaped planar arrangement pattern in which the first pixel column 71 in which the pixel 3a and the pixel 3b(IR) are alternately and repeatedly arranged in the X direction and the second pixel column 73 in which the pixel 3b(IR) is repeatedly arranged in the X direction with no gap are alternately and repeatedly arranged in the Y direction such that the pixels 3a in two first pixel columns 71 adjacent to each other are shifted from each other by one pixel in the X direction.

Furthermore, as a third modification, as illustrated in FIG. 9C, the pixel 3a and the pixel 3b(IR) may be arranged in an area-shaped planar arrangement pattern including a first pixel area 74 in which the pixel 3a is repeatedly arranged in each of the X direction and the Y direction with no gap and a second pixel area 75 in which the pixel 3b(IR) is repeatedly arranged in each of the X direction and the Y direction with no gap.

Furthermore, as a fourth modification, as illustrated in FIG. 9D, the pixel 3a and the pixel 3b(IR) may be arranged in a line-shaped planar pattern in which a first pixel column 72 in which the pixel 3a is repeatedly arranged in the X direction with no gap and the second pixel column 73 in which the pixel 3b(IR) is repeatedly arranged in the X direction with no gap are alternately and repeatedly arranged in the Y direction.

### Second Embodiment

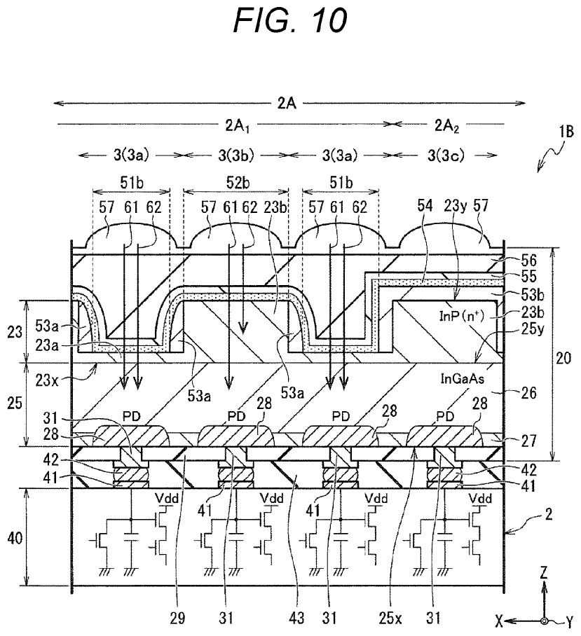

As illustrated in FIG. 10, a solid-state imaging device 1B according to a second embodiment of the present technology is basically similar in configuration to the solid-state imaging device 1A according to the first embodiment described above, but is different in the following configuration.

That is, as illustrated in FIG. 10, the solid-state imaging device 1B according to the second embodiment includes a first light transmitting part 51b and a second light transmitting part 52b instead of the first light transmitting part 51 and the second light transmitting part 52 illustrated in FIG. 4A of the first embodiment described above. Then, the solid-state imaging device 1B according to the second embodiment further includes a transparent electrode 54. The other configuration is almost similar to the configuration of the first embodiment described above.

As illustrated in FIG. 10, the transparent electrode 54 is provided between the second compound semiconductor layer 23 and the antireflection film 55, and between the light shielding films 53a and 53b, and the antireflection film 55. In a manner similar to the first compound semiconductor layer 25, the transparent electrode 54 is provided in common for all the pixels 3 (3a, 3b, 3c). Then, the transparent electrode 54 is in contact with and electrically connected to the first portion 23a of the second compound semiconductor layer 23 in the pixel 3a. Furthermore, the transparent electrode 54 is in contact with and electrically connected to the second portion 23b of the second compound semiconductor layer 23 in the pixel 3b. Furthermore, the transparent electrode 54 is in contact with the light shielding film 53b and is electrically connected to the second portion 23b of the second compound semiconductor layer 23 via the light shielding film 53b in the pixel 3c. The predetermined bias voltage Va is applied to both the transparent electrode 54 and the second compound semiconductor layer 23. That is, the transparent electrode 54 is provided as a backing electrode of the second compound semiconductor layer 23 that also functions as an electrode. As the transparent electrode 54, a material such as indium tin oxide (ITO) or ITiO(In₂O₃—TiO₂) capable of transmitting the infrared light 71 and the visible light 62 can be used.

As illustrated in FIG. 10, the first light transmitting part 51b is provided for each pixel 3a in a manner similar to the first light transmitting part 51 of the first embodiment described above, and the second light transmitting part 52b is provided for each pixel 3b in a manner similar to the second light transmitting part of the first embodiment described above. The first light transmitting part 51b and the second light transmitting part 52b each further include the transparent electrode 54 that transmits the infrared light 61 and the visible light 62, unlike the first light transmitting part 51 and the second light transmitting part 52 of the first embodiment described above.

In the second embodiment, the pixel 3a includes the first light transmitting part 51b that transmits the infrared light 61 and the visible light 62, and the photoelectric conversion element PD (first photoelectric conversion element) that photoelectrically converts the infrared light 61 and the visible light 62 that have passed through the first light transmitting part 51b. Furthermore, the pixel 3b includes the second light transmitting part 52b that transmits the infrared light but blocks the transmission of the visible light 62, and the photoelectric conversion element PD (second photoelectric conversion element) that photoelectrically converts the infrared light 61 that has passed through the second light transmitting part 52b. The pixel 3c includes the second portion 23b of the second compound semiconductor layer 23, the light shielding film 53b covering the upper and side surfaces of the second portion 23b, and the photoelectric conversion element PD (third photoelectric conversion element) provided in the first compound semiconductor layer 25 in alignment with the second portion 23b in plan view.

The solid-state imaging device 1B according to the second embodiment can also produce effects similar to the effects produced by the solid-state imaging device 1A according to the first embodiment described above.

Furthermore, since the solid-state imaging device 1B according to the second embodiment includes the transparent electrode 54 in common for each pixel 3 (3a, 3b, 3c), the predetermined bias voltage Va can be stably applied to the cathode side of the photoelectric conversion element PD included in each pixel 3 as compared to the first embodiment.

Note that in a case where the predetermined bias voltage Va can be stably applied to the cathode side of each photoelectric conversion element PD, the first portion 23a of the second compound semiconductor layer 23 may be omitted. In this case, the first light transmitting part 51b does not include the second compound semiconductor layer 23, and the second light transmitting part 52b includes the second compound semiconductor layer 23.

### Third Embodiment

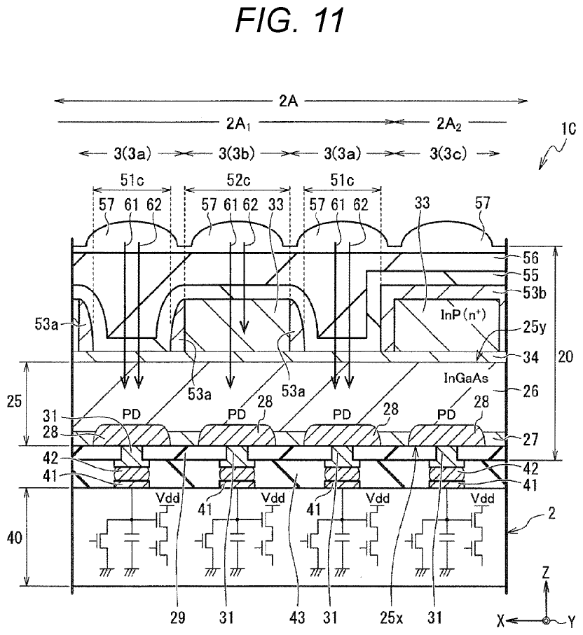

As illustrated in FIG. 11, a solid-state imaging device 1C according to a third embodiment of the present technology is basically similar in configuration to the solid-state imaging device 1A according to the first embodiment described above, but is different in the following configuration.

That is, as illustrated in FIG. 11, the solid-state imaging device 1C according to the third embodiment includes a first light transmitting part 51c, a second light transmitting part 52c, and a second compound semiconductor layer 33 instead of the first light transmitting part 51, the second light transmitting part 52, and the second compound semiconductor layer 23 illustrated in FIG. 4A of the first embodiment described above. Then, the solid-state imaging device 1C according to the third embodiment further includes an electrode layer 34. The other configuration is almost similar to the configuration of the first embodiment described above.

As illustrated in FIG. 11, the second compound semiconductor layer 33 is formed in an island shape, and is provided for each of the pixels 3b and 3c. Then, the second compound semiconductor layer 33 includes, for example, the same material as the material of the second compound semiconductor layer 23 of the first embodiment described above, and is similar in thickness to the second portion 23b of the second compound semiconductor layer 23. That is, the second compound semiconductor layer 33 also transmits the infrared light 61 but blocks the transmission of the visible light 62 in a manner similar to the second portion 23b of the second compound semiconductor layer 23 of the first embodiment described above.

As illustrated in FIG. 11, the electrode layer 34 is provided in common for all the pixels 3 (3a, 3b, 3c). The electrode layer 34 is provided between the first compound semiconductor layer 25 and the antireflection film 55 in the pixel 3a, and is provided between the first compound semiconductor layer 25 and the second compound semiconductor layer 33 in the pixels 3b and 3c. Then, the electrode layer 34 is covalently bonded to both the first compound semiconductor layer 25 and the second compound semiconductor layer 33. Then, the electrode layer 34 includes an n-type compound semiconductor that is highly doped as compared to the photoelectric conversion layer 26 of the first compound semiconductor layer 25, and is lower in sheet resistance than the photoelectric conversion layer 26. The predetermined bias voltage Va is applied to the electrode layer 34. The electrode layer 34 includes, for example, n-type InGaAs as a compound semiconductor material. The electrode layer 34 has such a thickness as to transmit the infrared light 61 and the visible light 62. The electrode layer 34 is electrically connected to both the first compound semiconductor layer 25 and the second compound semiconductor layer 33.

The first light transmitting part 51c is provided for each pixel 3a in a manner similar to the first light transmitting part 51 of the first embodiment described above. The second light transmitting part 52c is provided for each of the pixels 3b and 3c in a manner similar to the second light transmitting part 52 of the first embodiment described above. In the third embodiment, the first light transmitting part 51c includes the electrode layer 34 instead of the first portion 23a of the second compound semiconductor layer 23 illustrated in FIG. 4A of the first embodiment described above, and further includes the antireflection film 55 and the planarization film 56 that transmit the infrared light 61 and the visible light 62 in a manner similar to the first light transmitting part 51 of the first embodiment described above. Then, the second light transmitting part 52c includes the second compound semiconductor layer 33 and the electrode layer 34 instead of the second portion 23b of the second compound semiconductor layer 23 illustrated in FIG. 4A of the first embodiment described above, and further includes the antireflection film 55 and the planarization film 56 that transmit the infrared light 61 and the visible light in a manner similar to the second light transmitting part 52 of the first embodiment described above. That is, the first light transmitting part 51c of the third embodiment has a configuration in which the antireflection film 55 is in contact with the electrode layer 34 without the second compound semiconductor layer 33.

In the third embodiment, the pixel 3a includes the first light transmitting part 51c that transmits the infrared light 61 and the visible light 62, and the photoelectric conversion element PD (first photoelectric conversion element) that photoelectrically converts the infrared light 61 and the visible light 62 that have passed through the first light transmitting part 51c. Furthermore, the pixel 3b includes the second light transmitting part 52c that transmits the infrared light but blocks the transmission of the visible light 62, and the photoelectric conversion element PD (second photoelectric conversion element) that photoelectrically converts the infrared light 61 that has passed through the second light transmitting part 52c. The pixel 3c includes the second portion 23b of the second compound semiconductor layer 23, the light shielding film 53b covering the upper and side surfaces of the second portion 23b, and the photoelectric conversion element PD (third photoelectric conversion element) provided in the first compound semiconductor layer 25 in alignment with the second portion 23b in plan view.

The solid-state imaging device 1C according to the third embodiment can also produce effects similar to the effects produced by the solid-state imaging device 1A according to the first embodiment described above.

Furthermore, since the solid-state imaging device 1C according to the third embodiment includes the electrode layer 34 in common for each pixel 3 (3a, 3b, 3c), the predetermined bias voltage Va can be more stably applied to the cathode side of the photoelectric conversion element PD included in each pixel 3 (3a, 3b, 3c) even if the first light transmitting part 51c does not include the second compound semiconductor layer 33.

Note that the solid-state imaging device 1C according to the third embodiment may also include the transparent electrode 54 illustrated in FIG. 10 of the second embodiment described above.

### Fourth Embodiment

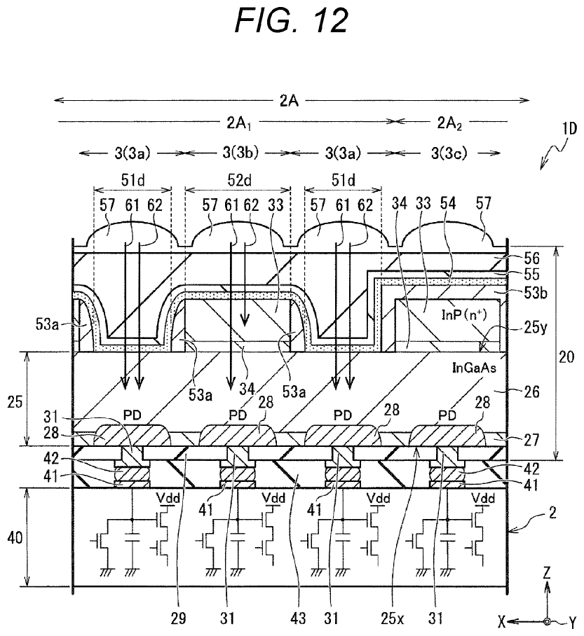

As illustrated in FIG. 12, a solid-state imaging device 1D according to a fourth embodiment of the present technology is basically similar in configuration to the solid-state imaging device 1C according to the third embodiment described above, but is different in the following configuration.

That is, as illustrated in FIG. 12, the solid-state imaging device 1D according to the fourth embodiment includes a first light transmitting part 51d and a second light transmitting part 52d instead of the first light transmitting part 51c and the second light transmitting part 52c illustrated in FIG. 11 of the third embodiment described above. Then, the solid-state imaging device 1D according to the fourth embodiment further includes the transparent electrode 54 in a manner similar to the solid-state imaging device 1B according to the second embodiment described above. The other configuration is almost similar to the configuration of the third embodiment described above.

As illustrated in FIG. 12, the transparent electrode 54 is provided between the first compound semiconductor layer 25 and the antireflection film 55, between the second compound semiconductor layer 33 and the antireflection film 55, and between the light shielding films 53a and 53b, and the antireflection film 55. In a manner similar to the first compound semiconductor layer 25, the transparent electrode 54 is provided in common for all the pixels 3 (3a, 3b, 3c). Then, the transparent electrode 54 is in contact with and electrically connected to the first compound semiconductor layer 25 in the pixel 3a. Furthermore, the transparent electrode 54 is in contact with and electrically connected to the second compound semiconductor layer 33 in the pixel 3b. Furthermore, the transparent electrode 54 is in contact with the light shielding film 53b and is electrically connected to the second compound semiconductor layer 33 via the light shielding film 53b in the pixel 3c. The predetermined bias voltage Va is applied to both the transparent electrode 54 and the second compound semiconductor layer 33.

As illustrated in FIG. 12, the first light transmitting part 51d is provided for each pixel 3a in a manner similar to the first light transmitting part 51c of the third embodiment described above. The second light transmitting part 52d is provided for each of the pixels 3b and 3c in a manner similar to the second light transmitting part 52c of the third embodiment described above. In the fourth embodiment, the first light transmitting part 51d includes neither the second compound semiconductor layer 33 nor the electrode layer unlike the first light transmitting part 51c of the third embodiment described above, and includes the transparent electrode 54, the antireflection film 55, and the planarization film 56 that transmit the infrared light 61 and the visible light 62. Then, in a manner similar to the second light transmitting part 52c of the third embodiment described above, the second light transmitting part 52d includes the second compound semiconductor layer 33 and the electrode layer 34, and further includes the antireflection film 55 and the planarization film 56 that transmit the infrared light 61 and the visible light 62. The electrode layer 34 of the fourth embodiment is selectively provided between the first compound semiconductor layer 25 and the second compound semiconductor layer 33 and is electrically connected to both the first and second compound semiconductor layers 25 and 33.

In the fourth embodiment, the pixel 3a includes the first light transmitting part 51d that transmits the infrared light 61 and the visible light 62, and the photoelectric conversion element PD (first photoelectric conversion element) that photoelectrically converts the infrared light 61 and the visible light 62 that have passed through the first light transmitting part 51d. Furthermore, the pixel 3b includes the second light transmitting part 52d that transmits the infrared light but blocks the transmission of the visible light 62, and the photoelectric conversion element PD (second photoelectric conversion element) that photoelectrically converts the infrared light 61 that has passed through the second light transmitting part 52d. The pixel 3c includes the second portion 23b of the second compound semiconductor layer 23, the light shielding film 53b covering the upper and side surfaces of the second portion 23b, and the photoelectric conversion element PD (third photoelectric conversion element) provided in the first compound semiconductor layer 25 in alignment with the second portion 23b in plan view.

The solid-state imaging device 1D according to the fourth embodiment can also produce effects similar to the effects produced by the solid-state imaging device 1C according to the third embodiment described above.

Furthermore, since the solid-state imaging device 1D according to the fourth embodiment includes the transparent electrode 54 in common for each pixel 3 (3a, 3b, 3c), the predetermined bias voltage Va can be stably applied to the cathode side of the photoelectric conversion element PD included in each pixel 3 (3a, 3b, 3c) even if the second light transmitting part 52d includes neither the second compound semiconductor layer nor the electrode layer 34.

### Fifth Embodiment

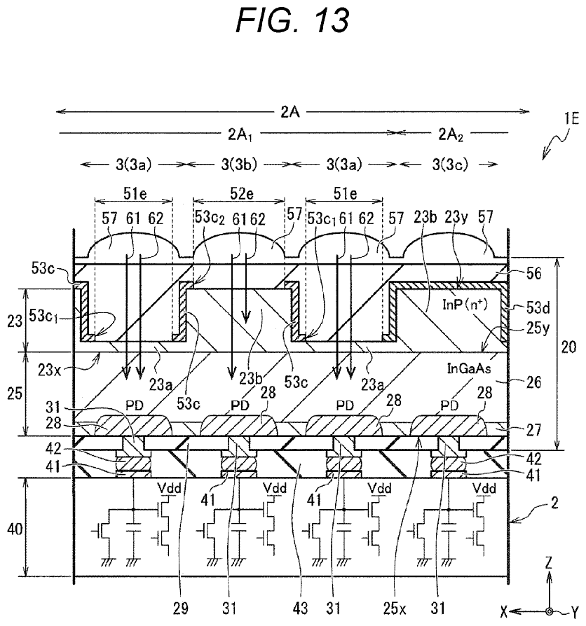

As illustrated in FIG. 13, a solid-state imaging device 1E according to a fifth embodiment of the present technology is basically similar in configuration to the solid-state imaging device 1A according to the first embodiment described above, but is different in the following configuration.

That is, as illustrated in FIG. 13, the solid-state imaging device 1E according to this embodiment includes light shielding films 53c and 53d instead of the light shielding films 53a and 53b illustrated in FIG. 4A of the first embodiment described above. Then, in the solid-state imaging device 1E according to the fifth embodiment, the antireflection film 55 illustrated in FIG. 4A of the first embodiment described above is omitted.

In the pixels 3a and 3b, the light shielding film 53c is provided over the first portion 23a and the second portion 23b of the second compound semiconductor layer 23 so as to cover the side surface of the second portion 23b of the second compound semiconductor layer 23, and terminates at each peripheral portion of the first portion 23a and the second portion 23b so as to expose each central portion of the first portion 23a and the second portion 23b. That is, the light shielding film 53c is provided over the first portion 23a and the second portion 23b of the second compound semiconductor layer 23, and has openings 53c₁ and 53c₂ in the upper surface of the first portion 23a and the upper surface of the second portion 23b, respectively. In the fifth embodiment, the planarization film 56 is in contact with the first portion 23a through the opening 53c₁ of the light shielding film 53c, and the planarization film 56 is in contact with the second portion 23b through the opening 53c₂ of the light shielding film 53c.

The light shielding film 53d is formed integrally with the light shielding film 53c, and covers the upper and side surfaces of the second portion 23b of the second compound semiconductor layer 23 in the pixel 3c.

It is possible to form the light shielding films 53c and 53d by forming a light shielding film all over the second compound semiconductor layer 23 including each surface of the first portion 23a and the second portion 23b to cover the second compound semiconductor layer 23, subsequently forming an etching mask separately on the first portion 23a and the second portion 23b by a well-known photolithography technique, and subsequently performing anisotropic etching on the light shielding film using the etching mask as a mask. As the light shielding films 53c and 53d, for example, a stacked film of titanium (Ti) and tungsten (W) can be used in a manner similar to the light shielding films 53a and 53b of the first embodiment described above.

A first light transmitting part 51e is provided for each pixel 3a in a manner similar to the first light transmitting part 51 of the first embodiment described above. A second light transmitting part 52e is provided for each of the pixels 3b and 3c in a manner similar to the second light transmitting part 52 of the first embodiment described above. In the fifth embodiment, the first light transmitting part 51e includes the first portion 23a of the second compound semiconductor 33 and further includes the planarization film 56 that transmits the infrared light 61 and the visible light 62, in a manner similar to the first light transmitting part 51 of the first embodiment described above. Then, the second light transmitting part 52e includes the second portion 23b of the second compound semiconductor layer 23 and further includes the planarization film 56 that transmits the infrared light 61 and the visible light 62, in a manner similar to the second light transmitting part 52c of the first embodiment described above.

In the fifth embodiment, the pixel 3a includes the first light transmitting part 51e that transmits the infrared light 61 and the visible light 62, and the photoelectric conversion element PD (first photoelectric conversion element) that photoelectrically converts the infrared light 61 and the visible light 62 that have passed through the first light transmitting part 51e. Furthermore, the pixel 3b includes the second light transmitting part 52e that transmits the infrared light but blocks the transmission of the visible light 62, and the photoelectric conversion element PD (second photoelectric conversion element) that photoelectrically converts the infrared light 61 that has passed through the second light transmitting part 52e. The pixel 3c includes the second portion 23b of the second compound semiconductor layer 23, the light shielding film 53d covering the upper and side surfaces of the second portion 23b, and the photoelectric conversion element PD (third photoelectric conversion element) provided in the first compound semiconductor layer 25 in alignment with the second portion 23b in plan view.

The solid-state imaging device 1E according to the fifth embodiment can also produce effects similar to the effects produced by the first embodiment described above.

Note that the solid-state imaging device 1E according to the fifth embodiment may also include the transparent electrode 54 illustrated in FIG. 10 of the second embodiment described above.

### Sixth Embodiment

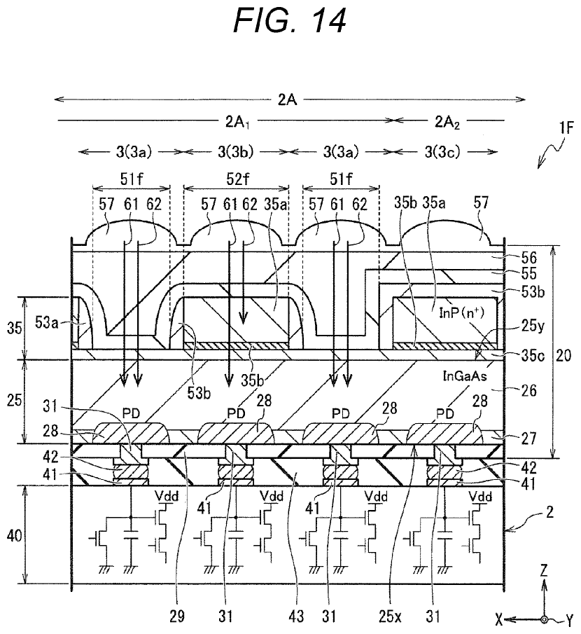

As illustrated in FIG. 14, a solid-state imaging device 1F according to a sixth embodiment of the present technology is basically similar in configuration to the solid-state imaging device 1A according to the first embodiment described above, but is different in the following configuration.

That is, as illustrated in FIG. 14, the solid-state imaging device 1F according to the sixth embodiment includes a first light transmitting part 51f and a second light transmitting part 52f instead of the first light transmitting parts 51 and 52 illustrated in FIG. 4A of the first embodiment described above. Then, the solid-state imaging device 1F according to the sixth embodiment includes a second compound semiconductor layer 35 instead of the second compound semiconductor layer 23 illustrated in FIG. 4A of the first embodiment described above. The other configuration is almost similar to the configuration of the first embodiment described above.

As illustrated in FIG. 14, the second compound semiconductor layer 35 is provided on the second surface 25y side of the first compound semiconductor layer 25. Then, the second compound semiconductor layer 35 has a stacked structure in which an upper layer 35a, an etching stopper layer 35b, and a lower layer 35c are epitaxially grown in this order on the growth substrate 21 illustrated in FIG. 8A of the first embodiment described above.

As illustrated in FIG. 14, the lower layer 35c is provided in common for all the pixels 3 (3a, 3b, 3c) and is covalently bonded to the first compound semiconductor layer 25, for example. The etching stopper layer 35b and the upper layer 35a are selectively provided in the pixels 3b and 3c and are not provided in the pixel 3a, for example. The etching stopper layer 35b is provided between the lower layer 35c and the upper layer 35a and is covalently bonded to both the lower layer 35c and the upper layer 35a.

The lower layer 35c and the upper layer 35a includes, for example, the same compound semiconductor (n-type InP) as the second compound semiconductor layer of the first embodiment described above. As the etching stopper layer 35b, any one of compound semiconductors of InGaSb, GaAsSb, InAlAs, and InGaAs can be used. Then, the lower layer 35c, the upper layer 35a, and the etching stopper layer 35b are each highly doped as compared to the photoelectric conversion layer 26 of the first compound semiconductor layer 25 and is lower in sheet resistance than the photoelectric conversion layer 26. The predetermined bias voltage Va is applied to the lower layer 35c.

The upper layer 35a has such a thickness (film thickness) as to transmit the infrared light 61 and block the transmission of the visible light 62. The etching stopper layer 35b and the lower layer 35c each have such a thickness (film thickness) as to transmit the infrared light 61 and the visible light 62.

As illustrated in FIG. 14, the antireflection film is provided between the second compound semiconductor layer 35 and the planarization film 56, and between the light shielding films 53a and 53b, and the planarization film 56. The antireflection film 55 is provided in common for all the pixels 3 (3a, 3b, 3c) in a manner similar to the antireflection film 55 of the first embodiment described above. Then, the antireflection film 55 is in contact with the lower layer 35c of the second compound semiconductor layer 35 in the pixel 3a, and is in contact with the upper layer 35a of the second compound semiconductor layer 35 in the pixels 3b and 3c.

As illustrated in FIG. 14, the first light transmitting part 51f is provided for each pixel 3a in a manner similar to the first light transmitting part 51 of the first embodiment described above. The second light transmitting part 52f is provided for each pixel 3b in a manner similar to the second light transmitting part 52 of the first embodiment described above. In the sixth embodiment, the first light transmitting part 51f includes the lower layer 35c of the second compound semiconductor layer 35, unlike the first light transmitting part 51 of the first embodiment described above, and further includes the antireflection film 55 and the planarization film 56 that transmit the infrared light 61 and the visible light 62. The second light transmitting part 52f includes the upper layer 35a, the etching stopper layer 35b, and the lower layer 35c of the second compound semiconductor layer 35, unlike the first light transmitting part 52 of the first embodiment described above, and further includes the antireflection film 55 and the planarization film 56 that transmit the infrared light 61 and the visible light 62. The first light transmitting part 51f transmits the infrared light and the visible light 62 in a manner similar to the first light transmitting part 51 of the first embodiment described above. Then, the second light transmitting part 52f transmits the infrared light 61 and blocks the transmission of the visible light 62 in a manner similar to the second light transmitting part 52 of the first embodiment described above.

In the sixth embodiment, the pixel 3a includes the first light transmitting part 51f that transmits the infrared light 61 and the visible light 62, and the photoelectric conversion element PD (first photoelectric conversion element) that photoelectrically converts the infrared light 61 and the visible light 62 that have passed through the first light transmitting part 51f. Furthermore, the pixel 3b includes the second light transmitting part 52f that transmits the infrared light but blocks the transmission of the visible light 62, and the photoelectric conversion element PD (second photoelectric conversion element) that photoelectrically converts the infrared light 61 that has passed through the second light transmitting part 52f. Furthermore, the pixel 3c includes the second compound semiconductor layer 35, the light shielding film 53b covering the upper and side surfaces of the second compound semiconductor layer 35, and the photoelectric conversion element PD (third photoelectric conversion element) provided in the first compound semiconductor layer 25 in alignment with the second compound semiconductor layer 35 in plan view.

The solid-state imaging device 1F according to the sixth embodiment can also produce effects similar to the effects produced by the solid-state imaging device 1A according to the first embodiment described above.

Furthermore, in the solid-state imaging device 1F according to the sixth embodiment, since the second compound semiconductor layer 35 includes the lower layer 35c in common for each pixel 3 (3a, 3b, 3c), the predetermined bias voltage Va can be stably applied to the cathode side of the photoelectric conversion element PD included in each pixel 3 (3a, 3b, 3c).

Note that the solid-state imaging device 1F according to the sixth embodiment may also include the transparent electrode 54 illustrated in FIG. 10 of the second embodiment described above.

### Seventh Embodiment

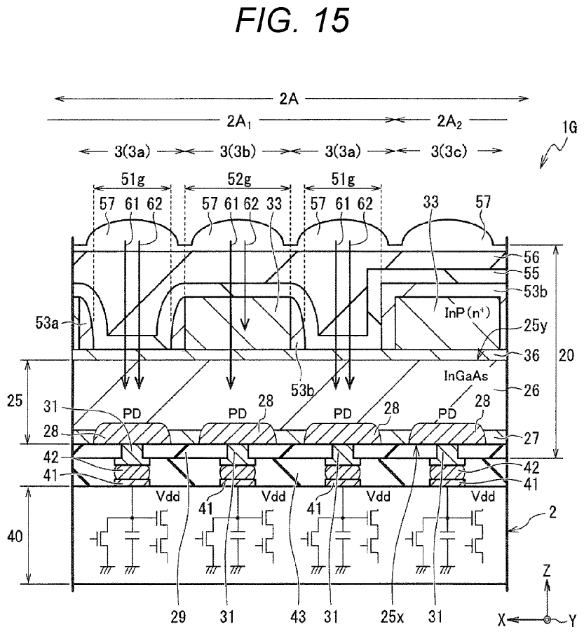

As illustrated in FIG. 15, a solid-state imaging device 1G according to a seventh embodiment of the present technology is basically similar in configuration to the solid-state imaging device 1C according to the third embodiment described above, but is different in the following configuration.

That is, as illustrated in FIG. 15, the solid-state imaging device 1G according to the seventh embodiment includes a first light transmitting part 51g, a second light transmitting part 52g, and an etching stopper layer instead of the first light transmitting part 51c, the second light transmitting part 52c, and the electrode layer 34 illustrated in FIG. 11 of the third embodiment described above. The other configuration is almost similar to the configuration of the third embodiment described above.

As illustrated in FIG. 15, the etching stopper layer 36 is provided in common for all the pixels 3 (3a, 3b, 3c). The etching stopper layer 36 is provided between the first compound semiconductor layer 25 and the antireflection film 55 in the pixel 3a, and is provided between the first compound semiconductor layer 25 and the second compound semiconductor layer 33 in the pixels 3b and 3c. Then, the etching stopper layer 36 is covalently bonded to both the first compound semiconductor layer 25 and the second compound semiconductor layer 33. The etching stopper layer 36 includes, for example, n-type InAlAs as a compound semiconductor material. The etching stopper layer 36 has such a thickness as to transmit the infrared light 61 and the visible light 62. The etching stopper layer 36 is highly doped as compared to the photoelectric conversion layer 26 of the first compound semiconductor layer 25, and is lower in sheet resistance than the photoelectric conversion layer 26. The predetermined bias voltage Va is applied to the etching stopper layer 36.

The first light transmitting part 51g is provided for each pixel 3a in a manner similar to the first light transmitting part 51c of the third embodiment described above. The second light transmitting part 52g is provided for each of the pixels 3b and 3c in a manner similar to the second light transmitting part 52c of the third embodiment described above. In the seventh embodiment, the first light transmitting part 51g includes the etching stopper layer 36, and further includes the antireflection film 55 and the planarization film 56 that transmit the infrared light 61 and the visible light 62. Then, the second light transmitting part 52g includes the second compound semiconductor layer and the etching stopper layer 36, and further includes the antireflection film 55 and the planarization film 56 that transmit the infrared light 61 and the visible light 62.

In the seventh embodiment, the pixel 3a includes the first light transmitting part 51g that transmits the infrared light 61 and the visible light 62, and the photoelectric conversion element PD (first photoelectric conversion element) that photoelectrically converts the infrared light 61 and the visible light 62 that have passed through the first light transmitting part 51f. Furthermore, the pixel 3b includes the second light transmitting part 52g that transmits the infrared light but blocks the transmission of the visible light 62, and the photoelectric conversion element PD (second photoelectric conversion element) that photoelectrically converts the infrared light 61 that has passed through the second light transmitting part 52g. The pixel 3c includes the second compound semiconductor layer 33, the light shielding film 53b covering the upper and side surfaces of the second compound semiconductor layer 33, and the photoelectric conversion element PD (third photoelectric conversion element) provided in the first compound semiconductor layer 25 in alignment with the second compound semiconductor layer 33 in plan view.

The solid-state imaging device 1G according to the seventh embodiment can also produce effects similar to the effects produced by the solid-state imaging device 1C according to the third embodiment described above.

Furthermore, since the solid-state imaging device 1C according to the seventh embodiment includes the etching stopper layer 36 in common for each pixel 3 (3a, 3b, 3c), the predetermined bias voltage Va can be stably applied to the cathode side of the photoelectric conversion element PD included in each pixel 3 (3a, 3b, 3c) even if the first light transmitting part 51g does not include the second compound semiconductor layer 33.

Note that the solid-state imaging device 1C according to the third embodiment may also include the transparent electrode 54 illustrated in FIG. 10 of the second embodiment described above.

### Eighth Embodiment

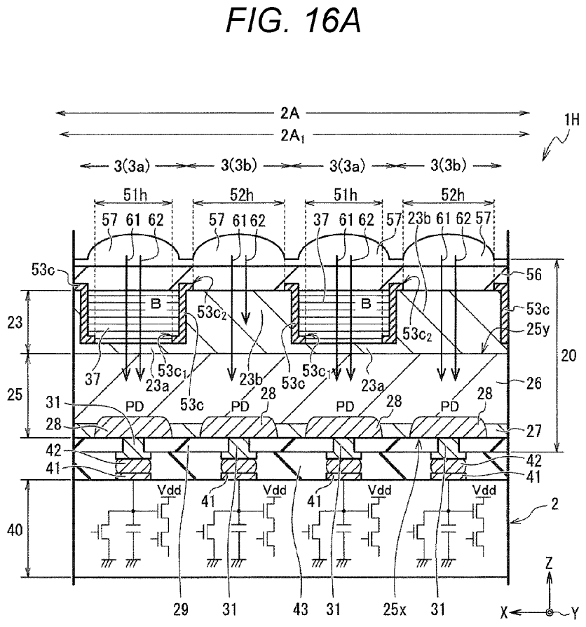

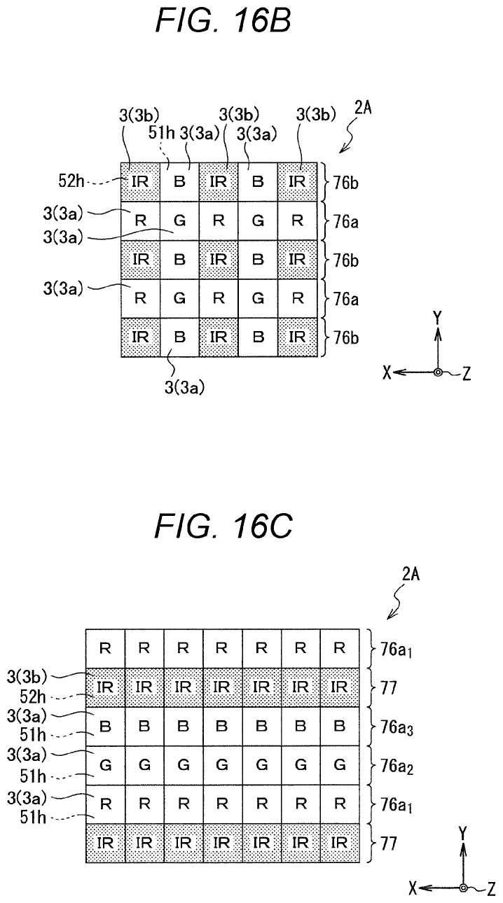

A solid-state imaging device 1H according to an eighth embodiment of the present technology will be described with reference to FIGS. 16A and 16B. Note that, in FIG. 16A, the pixel 3c illustrated in FIG. 13 of the fifth embodiment described above is not illustrated, and two pixels 3a and two pixels 3b are illustrated. Furthermore, for the sake of simplicity, each pixel 3 (3a, 3b, 3d) in FIG. 16A is made different in arrangement order from the pixel 3 (3a, 3b) illustrated in FIG. 16B.

As illustrated in FIG. 16A, the solid-state imaging device 1H according to the eighth embodiment of the present technology is basically similar in configuration to the solid-state imaging device 1E according to the fifth embodiment described above, but is different in the following configuration.

That is, as illustrated in FIG. 16A, the solid-state imaging device 1H according to this embodiment includes a first light transmitting part 51h and a second light transmitting part 52h instead of the first light transmitting part 51e and the second light transmitting part 52e illustrated in FIG. 13 of the fifth embodiment described above. Then, the solid-state imaging device 1H according to the eighth embodiment further includes a color filter 37.

The color filter 37 is selectively provided between the first portion 23a of the second compound semiconductor layer 23 and the planarization film 56 so as to fill a step generated due to a difference in thickness between the first portion 23a and the second portion 23b of the second compound semiconductor layer 23. Therefore, the color filter 37 is not provided between the second portion 23b of the second compound semiconductor layer 23 and the planarization film. In the eighth embodiment, the color filter 37 is in contact with the first portion 23a of the second compound semiconductor layer 23 through the opening 53c₁ of the light shielding film 53c, and the planarization film 56 is in contact with the second portion 23b through the opening 53c₂ of the light shielding film 53c.

As illustrated in FIG. 16A, the first light transmitting part 51h is provided for each pixel 3a in a manner similar to the first light transmitting part 51e of the fifth embodiment described above. The second light transmitting part 52h is provided for each pixel 3b in a manner similar to the second light transmitting part 52e of the fifth embodiment described above. In the eighth embodiment, the first light transmitting part 51h includes the color filter 37 unlike the first light transmitting part 51e of the third embodiment described above, and further includes the first portion 23a of the second compound semiconductor layer 23 and the planarization film 56 in a manner similar to the first light transmitting part 51e of the third embodiment described above. The second light transmitting part 52h includes the second portion 23b of the second compound semiconductor layer 23 and the planarization film 56 in a manner similar to the second light transmitting part 52e of the fifth embodiment described above.

The color filter 37 includes, for example, any one of a red (R) first color filter, a green (G) second color filter, and a blue (B) third color filter. Then, in the pixel region 2A of the eighth embodiment, as illustrated in FIG. 16B, a pixel 3a(R) including the red first color filter, a pixel 3a(G) including the green second color filter, and a pixel 3a(B) including the blue third color filter are provided as the pixels 3a. The color filter transmits infrared light and visible light. The color filter 37 includes, for example, a thermosetting resin to which a pigment is added.

The first light transmitting part 51h is provided for each pixel 3a in a manner similar to the first light transmitting part 51e of the fifth embodiment described above. The second light transmitting part 52h is provided for each of the pixels 3b and 3c in a manner similar to the second light transmitting part 52e of the fifth embodiment described above. In the ninth embodiment, the first light transmitting part 51h includes the first portion 23a of the second compound semiconductor 33 in a manner similar to the first light transmitting part 51 of the fifth embodiment described above and further includes the color filter 37 that transmits the infrared light 61 and the visible light 62. Then, the second light transmitting part 52h includes the second portion 23b of the second compound semiconductor layer 23 and further includes the planarization film 56 that transmits the infrared light 61 and the visible light 62, in a manner similar to the second light transmitting part 52e of the third embodiment described above.

In the eighth embodiment, the pixel 3a includes the first light transmitting part 51h that transmits the infrared light 61 and the visible light 62, and the photoelectric conversion element PD (first photoelectric conversion element) that photoelectrically converts the infrared light 61 and the visible light 62 that have passed through the first light transmitting part 51h. Furthermore, the pixel 3b includes the second light transmitting part 52h that transmits the infrared light but blocks the transmission of the visible light 62, and the photoelectric conversion element PD (second photoelectric conversion element) that photoelectrically converts the infrared light 61 that has passed through the second light transmitting part 52h.

As illustrated in FIG. 16B, the pixel 3a(R, G, B) including the first light transmitting part 51h and the pixel 3b(IR) including the second light transmitting part 52h are arranged in, but not limited to, a planar arrangement pattern in which, for example, a first pixel column 76a in which the pixel 3a(R) and the pixel 3a(G) are repeatedly arranged in this order in the X direction with no gap, and a second pixel column 76b in which the pixel 3a(B) and the pixel 3b(IR) are alternately and repeatedly arranged in the X direction with no gap are alternately and repeatedly arranged in the Y direction.

The solid-state imaging device 1H according to the eighth embodiment can also produce effects similar to the effects produced by the solid-state imaging device 1E according to the fifth embodiment described above.

Note that, as illustrated in FIG. 16C, the arrangement of the pixel 3a(R, G, B) including the first light transmitting part 51h and the pixel 3b(IR) including the second light transmitting part 52h may be arranged in a planar arrangement pattern in which a first pixel column 76a₁ in which the pixel 3a(R) is repeatedly arranged in the X direction with no gap, a second pixel column 76a₂ in which the pixel 3a(G) is repeatedly arranged in the X direction with no gap, a third pixel column 76a₃ in which the pixel 3a(B) is repeatedly arranged in the X direction with no gap, and a fourth pixel column 77 in which the pixel 3b(IR) is repeatedly arranged in the X direction with no gap are repeatedly arranged in this order in the Y direction.

Furthermore, the solid-state imaging device 1H according to the eighth embodiment may also include the transparent electrode 54 illustrated in FIG. 10 of the second embodiment described above.

### Ninth Embodiment

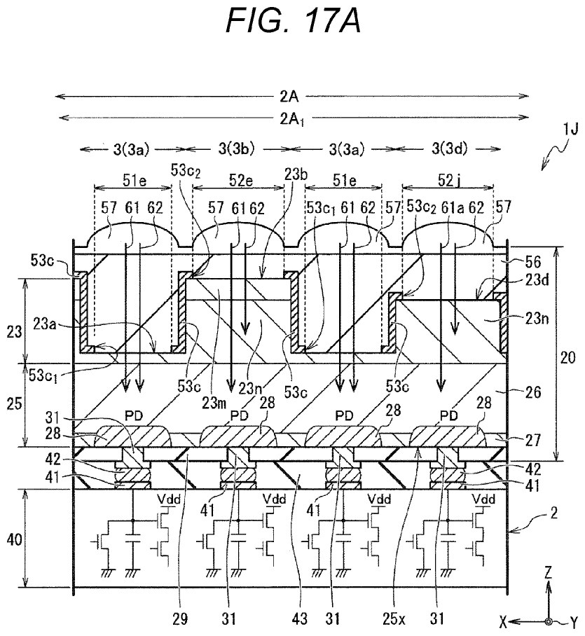

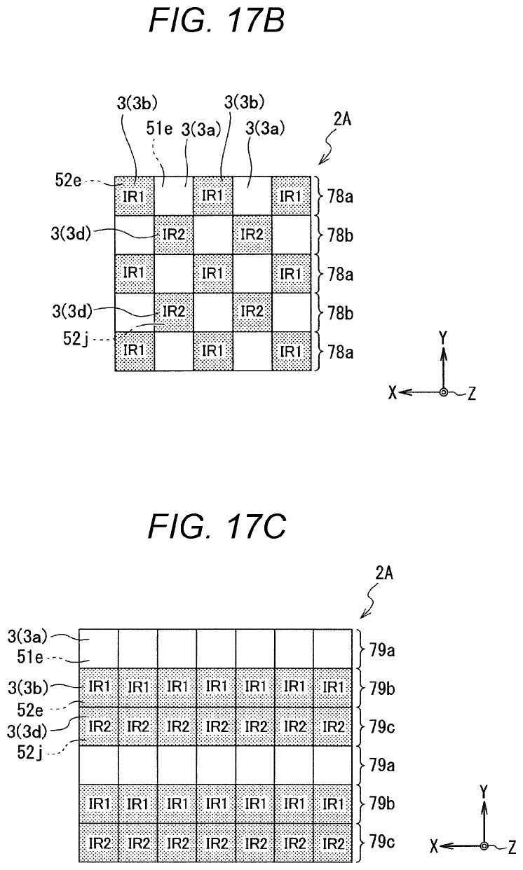

A solid-state imaging device 1J according to a ninth embodiment of the present technology will be described with reference to FIGS. 17A and 17B. Note that, in FIG. 17A, the pixel 3c illustrated in FIG. 13 of the fifth embodiment described above is not illustrated, and two pixels 3a, one pixel 3b, and one pixel 3d are illustrated. Furthermore, for the sake of simplicity, each pixel 3 (3a, 3b, 3d) in FIG. 17A is made different in arrangement order from the pixel 3 (3a, 3b, 3d) illustrated in FIG. 17B.

As illustrated in FIG. 17A, the solid-state imaging device 1J according to the ninth embodiment of the present technology is basically similar in configuration to the solid-state imaging device 1E according to the fifth embodiment described above, but is different in the following configuration.

That is, as illustrated in FIG. 17A, the solid-state imaging device 1J according to the ninth embodiment includes, as a fourth pixel, the pixel 3d including a third light transmitting part 52j. Then, the second compound semiconductor layer 23 of the ninth embodiment has a two-layer structure unlike the second compound semiconductor layer 23 of the fifth embodiment described above. The other configuration is almost similar to the configuration of the fifth embodiment described above.

As illustrated in FIG. 17A, the pixel 3d includes the third light transmitting part 52j that is provided on the light incident surface side, which is the second surface 25y side, of the first compound semiconductor layer 25 and transmits infrared light 61a and blocks the transmission of the visible light 62, and the photoelectric conversion element PD as a fourth photoelectric conversion element that is provided on the light incident surface side (the second surface 25y side) of the first compound semiconductor layer 25 and photoelectrically converts the infrared light 61a that has passed through the third light transmitting part 52j.

The second compound semiconductor layer 23 is provided on the second surface 25y side of the first compound semiconductor layer 25 in common for all the pixels 3 (3a, 3b, 3c, 3d). Then, the second light transmitting part 52e and the third light transmitting part 52j are different in thicknesses of the second compound semiconductor layer 23 from each other, and for example, the third light transmitting part 52j is smaller in thickness than the second light transmitting part 52e. In other words, the pixel 3b and the pixel 3d are different in thickness of the two-compound semiconductor layer 23 from each other, and for example, the pixel 3d is smaller in thickness than the pixel 3b. That is, the second compound semiconductor layer 23 of the ninth embodiment includes the first portion 23a and the second portion 23b in a manner similar to the fifth embodiment described above, and further includes a third portion 23d that is thinner than the second portion. Then, the third light transmitting part 52j includes the third portion 23d of the second compound semiconductor layer 23. The second portion 23b and the third portion 23d of the second compound semiconductor layer 23 have such thicknesses as to transmit infrared light in different wavelength bands.

Unlike the second compound semiconductor layer 23 of the fifth embodiment described above, the second compound semiconductor layer 23 has a stacked structure in which a first material film 23m and a second material film 23n are epitaxially grown in this order on the growth substrate 21 illustrated in FIG. 8A of the first embodiment. In FIG. 17A, the second compound semiconductor layer 23 has a stacked structure in which the second material film 23n and the first material film 23m are sequentially arranged from the second surface 25y side of the first compound semiconductor layer 25.

As the first material film 23m, a group III-V compound semiconductor such as InGaAs, GaAsSb, InGaAsP, or InGaAs can be used. In the ninth embodiment, for example, InGaAs containing n-type impurities is used as the first material film 23m.

As the second material film 23n, for example, InP containing n-type impurities as a group III-V compound semiconductor is used.

The first light transmitting part 51e includes the first portion 23a of the second compound semiconductor layer 23. Then, the first portion 23a includes the second material film 23n, and does not include the first material film 23m.

The second light transmitting part 52e includes the second portion 23b of the second compound semiconductor layer 23. Then, the second portion 23b includes the second material film 23n larger in film thickness than the second material film 23n in the first portion 23a, and further includes the first material film 23m.

The third light transmitting part 52j includes the third portion 23d of the second compound semiconductor layer 23. Then, the third portion 23d includes the second material film 23n similar in film thickness to the second material film 23n in the second portion 23b, but does not include the first material film 23m.

The first light transmitting part 51e is provided for each pixel 3a in a manner similar to the first light transmitting part 51e of the fifth embodiment described above. The second light transmitting part 52e is provided for each of the pixels 3b and 3c in a manner similar to the second light transmitting part 52e of the fifth embodiment described above. The third light transmitting part 52j is provided for each pixel 3d. In the ninth embodiment, the first light transmitting part 51e includes the first portion 23a of the second compound semiconductor layer 23 and further includes the planarization film 56 that transmits the infrared light and the visible light 62, in a manner similar to the first light transmitting part 51e of the fifth embodiment described above. Then, the second light transmitting part 52e includes the second portion 23b of the compound semiconductor layer 23, and further includes the planarization film 56 that transmits the infrared light and the visible light 62. Then, the third light transmitting part 52j includes the third portion 23d of the second compound semiconductor layer 23, and further includes the planarization film 56 that transmits the infrared light 61 and the visible light 62. The second light transmitting part 52e transmits the infrared light in a predetermined wavelength band, and the third light transmitting part 52j transmits the infrared light 61a in a wavelength band different from the infrared light 61.

In the ninth embodiment, the pixel 3a includes the first light transmitting part 51e that transmits the infrared light 61 and the visible light 62, and the photoelectric conversion element PD (first photoelectric conversion element) that photoelectrically converts the infrared light 61 and the visible light 62 that have passed through the first light transmitting part 51e. Furthermore, the pixel 3b includes the second light transmitting part 52e that transmits the infrared light but blocks the transmission of the visible light 62, and the photoelectric conversion element PD (second photoelectric conversion element) that photoelectrically converts the infrared light 61 that has passed through the second light transmitting part 52e. Furthermore, the pixel 3d includes the third light transmitting part 52j that transmits the infrared light 61a in a wavelength band different from the infrared light 61 that passes through the second light transmitting part 52e of the pixel 3b, but blocks the transmission of the visible light 62, and the photoelectric conversion element (fourth photoelectric conversion element) PD that photoelectrically converts the infrared light 61a that has passed through the third light transmitting part 52j.

As illustrated in FIG. 17B, the pixel 3a including the first light transmitting part 51e, the pixel 3b(IR1) including the second light transmitting part 52e, and the pixel 3d(IR2) including the third light transmitting part 52j are arranged in, but not limited to, a planar arrangement pattern in which, for example, a first pixel column 78a in which the pixel 3a and the pixel 3b(IR1) are alternately and repeatedly arranged in the X direction with no gap, and a second pixel column 78b in which the pixel 3a and the pixel 3d(IR2) are alternately and repeatedly arranged in the X direction with no gap are alternately and repeatedly arranged in the Y direction.

The solid-state imaging device 1J according to the ninth embodiment can also produce effects similar to the effects produced by the solid-state imaging device 1A according to the first embodiment described above.

Furthermore, in the solid-state imaging device 1J according to the ninth embodiment, since the second light transmitting part 52e of the pixel 3b transmits the infrared light 61 in a predetermined wavelength band, and the third light transmitting part 52j of the pixel 3d transmits the infrared light 61a in a wavelength band different from the infrared light 61 that passes through the second light transmitting part 52e, it is possible to separate infrared light and to photoelectrically convert the infrared light 61 and the infrared light 61a in different wavelength bands.

Note that, as illustrated in FIG. 17C, the pixel 3a including the first light transmitting part 51e, the pixel 3b including the second light transmitting part 52e, and the pixel 3d including the third light transmitting part 52j may be arranged in a planar arrangement pattern in which a first pixel column 79a in which the pixel 3a is repeatedly arranged in the X direction with no gap, a second pixel column 79b in which the pixel 3b is repeatedly arranged in the X direction with no gap, and a third pixel column 79c in which the pixel 3d is repeatedly arranged in the X direction with no gap are repeatedly arranged in this order in the Y direction.

Furthermore, the solid-state imaging device 1J according to the ninth embodiment may also include the transparent electrode 54 illustrated in FIG. 10 of the second embodiment described above.

### Tenth Embodiment

<<Application Example to Electronic Device>>

The present technology (technology according to the present disclosure) can be applied to various electronic devices such as an imaging device such as a digital still camera or a digital video camera, a mobile phone having an imaging function, or other devices having an imaging function.

FIG. 18 is a diagram illustrating a schematic configuration of an electronic device (for example, a camera) according to the second embodiment of the present technology.

As illustrated in FIG. 18, an electronic device 100 includes a solid-state imaging device 101, an optical lens 102, a shutter device 103, a drive circuit 104, and a signal processing circuit 105. The electronic device indicates an embodiment in a case where the solid-state imaging devices 1A, 1B, 1C, 1D, 1E, 1F, 1G, 1H, and 1J according to the first to ninth embodiments of the present technology are each used as the solid-state imaging device 101 in an electronic device (for example, a camera).

The optical lens 102 forms an image of image light (incident light 106) from a subject on an imaging surface of the solid-state imaging device 101. As a result, signal charges are accumulated in the solid-state imaging device 101 over a certain period. The shutter device 103 controls a light irradiation period and a light shielding period for the solid-state imaging device 101. The drive circuit 104 supplies a drive signal for controlling a transfer operation of the solid-state imaging device 101 and a shutter operation of the shutter device 103. A signal of the solid-state imaging device 101 is transferred in response to a drive signal (timing signal) supplied from the drive circuit 104. The signal processing circuit 105 performs various types of signal processing on a signal (pixel signal) output from the solid-state imaging device 101. A video signal subjected to the signal processing is stored in a storage medium such as a memory or output to a monitor.

With such a configuration, the electronic device 100 according to the tenth embodiment causes a light antireflection part in the solid-state imaging device 101 to inhibit light reflection off a light shielding film or an insulating film in contact with an air layer, so that it is possible to inhibit deviation and to improve image quality.

Note that the electronic device 100 to which the solid-state imaging device 101 can be applied is not limited to a camera, and the solid-state imaging device 101 can also be applied to other electronic devices. For example, the solid-state imaging device 101 may be applied to an imaging device such as a camera module for a mobile device such as a mobile phone or a tablet terminal.

Note that the present technology may have the following configurations.

(1)

A solid-state imaging device including
a pixel region in which a plurality of pixels is arranged in a matrix, in which
the plurality of pixels includes a first pixel and a second pixel,
the first pixel includes a first light transmitting part that is provided on a light incident surface side of a first compound semiconductor layer and transmits infrared light and visible light, and a first photoelectric conversion element that is provided in the first compound semiconductor layer and photoelectrically converts the infrared light and the visible light that have passed through the first light transmitting part, and
the second pixel includes a second light transmitting part including a second compound semiconductor layer, the second light transmitting part being provided on the light incident surface side of the first compound semiconductor layer and transmitting the infrared light and blocking the transmission of the visible light, and a second photoelectric conversion element that photoelectrically converts the infrared light that has passed through the second light transmitting part.

(2)

The solid-state imaging device according to the above (1), in which
the first light transmitting part and the first photoelectric conversion element are aligned with each other in plan view, and
the second light transmitting part and the second photoelectric conversion element are aligned with each other in plan view.

(3)

The solid-state imaging device according to the above (1) or (2), in which
the second compound semiconductor layer includes a first portion formed with such a thickness as to transmit the infrared light and the visible light and a second portion formed with such a thickness as to transmit the infrared light and block the transmission of the visible light,
the first light transmitting part includes the first portion of the second compound semiconductor layer, and
the second light transmitting part includes the second portion of the second compound semiconductor layer.

(4)

The solid-state imaging device according to the above (3), in which
the first compound semiconductor layer includes a photoelectric conversion layer that absorbs the infrared light and the visible light to generate a charge, and
the second compound semiconductor layer is highly doped as compared to the photoelectric conversion layer.

(5)

The solid-state imaging device according to any one of the above (1) to (4), further including a first light shielding film provided on a side wall of the second compound semiconductor layer in the second light transmitting part.

(6)

The solid-state imaging device according to any one of the above (1) to (5), in which
the plurality of pixels further includes a third pixel, and
the third pixel includes the second compound semiconductor layer, a second light shielding film covering upper and side surfaces of the second compound semiconductor layer, and a third photoelectric conversion element provided in the first compound semiconductor layer in alignment in plan view.

(7)

The solid-state imaging device according to any one of the above (1) to (6), in which each of the first and second light transmitting parts includes an electrode layer, the electrode layer being provided between the first compound semiconductor layer and the second compound semiconductor layer in common for the first and second pixels and being electrically connected to both the first and second compound semiconductor layers.

(8)

The solid-state imaging device according to any one of the above (1) to (6), in which the second light transmitting part includes an electrode layer, the electrode layer being selectively provided between the first compound semiconductor layer and the second compound semiconductor layer and being electrically connected to both the first and second compound semiconductors.

(9)

The solid-state imaging device according to claim 1 of any one of the above (1) to (6), in which the second compound semiconductor layer includes an etching stopper layer between an upper layer and a lower layer.

(10)

The solid-state imaging device according to claim 1 of any one of the above (1) to (6), further including an etching stopper layer provided between the first compound semiconductor layer and the second compound semiconductor layer over the first pixel and the second pixel.

(11)

The solid-state imaging device according to claim 1 of any one of the above (1) to (10), in which the first light transmitting part includes a color filter.

(12)

The solid-state imaging device according to any one of the above (1) to (11), in which
the plurality of pixels further includes a fourth pixel,
the fourth pixel includes a third light transmitting part that is provided on the light incident surface side of the first compound semiconductor layer and includes the second compound semiconductor layer, and a fourth photoelectric conversion element that photoelectrically converts the infrared light that has passed through the third light transmitting part, and
the second compound semiconductor layer is different in film thickness between the second light transmitting part and the third light transmitting part.

(13)

The solid-state imaging device according to any one of the above (1) to (12), in which each of the first and second light transmitting parts includes a transparent electrode, the transparent electrode being provided on side of the second compound semiconductor layer remote from the first compound semiconductor layer in common for the first and second pixels and being electrically connected to both the first and second compound semiconductor layers.

(14)

The solid-state imaging device according to any one of the above (1) to (13), in which the second compound semiconductor layer is wider in band gap than the first compound semiconductor layer.

(15)

The solid-state imaging device according to any one of the above (1) to (14), in which the second compound semiconductor layer is covalently bonded to the first compound semiconductor layer.

(16)

The solid-state imaging device according to any one of the above (1) to (14), in which the second compound semiconductor layer and the first compound semiconductor layer include different compound semiconductor materials.

(17)

The solid-state imaging device according to any one of the above (1) to (16), in which the second compound semiconductor layer includes any one of InGaAs, GaAsSb, InGaAsP, InGaAlAs, InP, InAlAs, InAlAsSb, AlAsSb, AlAsSb, InAsP, or InSbP.

(18)

The solid-state imaging device according to any one of the above (1) to (17), in which the first compound semiconductor layer includes any one of InGaAs, Ex. InGaAs, or an InGaAs/GaAsSb superlattice.

(19)

The solid-state imaging device according to any one of the above (1) to (18), in which the first and second light transmitting parts are alternately and repeatedly arranged in each of an X direction and a Y direction orthogonal to each other in plan view.

(20)

An electronic device including:
a solid-state imaging device; an optical lens that forms an image of image light from a subject on an imaging surface of the solid-state imaging device; and a signal processing circuit that performs signal processing on a signal output from the solid-state imaging device, in which
the solid-state imaging device includes
a pixel region in which a plurality of pixels is arranged in a matrix,
the plurality of pixels includes a first pixel and a second pixel,
the first pixel includes a first light transmitting part that is provided on a light incident surface side of a first compound semiconductor layer and transmits infrared light and visible light, and a first photoelectric conversion element that is provided in the first compound semiconductor layer and photoelectrically converts the infrared light and the visible light that have passed through the first light transmitting part, and
the second pixel includes a second light transmitting part including a second compound semiconductor layer, the second light transmitting part being provided on the light incident surface side of the first compound semiconductor layer and transmitting the infrared light and blocking the transmission of the visible light, and a second photoelectric conversion element that photoelectrically converts the infrared light that has passed through the second light transmitting part.

The scope of the present technology is not limited to the illustrated and described exemplary embodiments, and includes all embodiments that provide effects equivalent to the effects intended to be provided by the present technology. Moreover, the scope of the present technology is not limited to the combinations of the features of the invention defined by the claims, and may be defined by any desired combination of specific features among all the disclosed features.

### REFERENCE SIGNS LIST

1A, 1B, 1C, 1D, 1E, 1F, 1G, 1H, 1J Solid-state imaging device
Semiconductor chip
2A Pixel region
2B Peripheral region
2A₁ Effective pixel region
2A₂ Optical black region
3, 3a, 3b, 3c Pixel
4 Vertical drive circuit
5 Column signal processing circuit
6 Horizontal drive circuit
7 Output circuit
8 Control circuit
10 Pixel drive line
12 Horizontal signal line
13 Logic circuit
14 Bonding pad
15 Readout circuit
20 Photoelectric conversion substrate part
21 Growth substrate
22 Etching stopper layer
23 Second compound semiconductor layer
23a First portion
23b Second portion
23c Third portion
23m First material film
23n Second material film
23x First surface
23y Second surface
25 First compound semiconductor layer
25x First surface
25y Second surface
26 Photoelectric conversion layer
27 Cap layer
28 Contact region
29 Protective film
29a Opening
31 Connection electrode (element side electrode)
33 Second compound semiconductor layer
34 Electrode layer
35 Second compound semiconductor layer
35a Upper layer
35b Etching stopper layer
35c Lower layer
36 Etching stopper layer
37 Color filter
40 Circuit substrate part
41 Connection electrode (circuit-side connection electrode)
42 Bump electrode
43 Insulating layer
51, 51b, 51c, 51d, 51e, 51f, 51g, 51h First light transmitting part
52, 52b, 52c, 52d, 52e, 52f, 52g, 52h Second light transmitting part
52j Third light transmitting part
53, 53a, 53b Light shielding film
54 Transparent electrode
55 Antireflection film
56 Planarization film
57 Microlens (on-chip lens)

1. A solid-state imaging device comprising
a pixel region in which a plurality of pixels is arranged in a matrix, wherein
the plurality of pixels includes a first pixel and a second pixel,
the first pixel includes a first light transmitting part that is provided on a light incident surface side of a first compound semiconductor layer and transmits infrared light and visible light, and a first photoelectric conversion element that is provided in the first compound semiconductor layer and photoelectrically converts the infrared light and the visible light that have passed through the first light transmitting part, and
the second pixel includes a second light transmitting part including a second compound semiconductor layer, the second light transmitting part being provided on the light incident surface side of the first compound semiconductor layer and transmitting the infrared light and blocking the transmission of the visible light, and a second photoelectric conversion element that photoelectrically converts the infrared light that has passed through the second light transmitting part.

2. The solid-state imaging device according to claim 1, wherein
the first light transmitting part and the first photoelectric conversion element are aligned with each other in plan view, and
the second light transmitting part and the second photoelectric conversion element are aligned with each other in plan view.

3. The solid-state imaging device according to claim 1, wherein
the second compound semiconductor layer includes a first portion formed with such a thickness as to transmit the infrared light and the visible light and a second portion formed with such a thickness as to transmit the infrared light and block the transmission of the visible light,
the first light transmitting part includes the first portion of the second compound semiconductor layer, and
the second light transmitting part includes the second portion of the second compound semiconductor layer.

4. The solid-state imaging device according to claim 3, wherein
the first compound semiconductor layer includes a photoelectric conversion layer that absorbs the infrared light and the visible light to generate a charge, and
the second compound semiconductor layer is highly doped as compared to the photoelectric conversion layer.

5. The solid-state imaging device according to claim 1, further comprising a first light shielding film provided on a side wall of the second compound semiconductor layer in the second light transmitting part.

6. The solid-state imaging device according to claim 1, wherein
the plurality of pixels further includes a third pixel, and
the third pixel includes the second compound semiconductor layer, a second light shielding film covering upper and side surfaces of the second compound semiconductor layer, and a third photoelectric conversion element provided in the first compound semiconductor layer in alignment in plan view.

7. The solid-state imaging device according to claim 1, wherein each of the first and second light transmitting parts includes an electrode layer, the electrode layer being provided between the first compound semiconductor layer and the second compound semiconductor layer in common for the first and second pixels and being electrically connected to both the first and second compound semiconductor layers.

8. The solid-state imaging device according to claim 1, wherein the second light transmitting part includes an electrode layer, the electrode layer being selectively provided between the first compound semiconductor layer and the second compound semiconductor layer and being electrically connected to both the first and second compound semiconductors.

9. The solid-state imaging device according to claim 1, wherein the second compound semiconductor layer includes an etching stopper layer between an upper layer and a lower layer.

10. The solid-state imaging device according to claim 1, further comprising an etching stopper layer provided between the first compound semiconductor layer and the second compound semiconductor layer over the first pixel and the second pixel.

11. The solid-state imaging device according to claim 1, wherein the first light transmitting part includes a color filter.

12. The solid-state imaging device according to claim 1, wherein
the plurality of pixels further includes a fourth pixel,
the fourth pixel includes a third light transmitting part that is provided on the light incident surface side of the first compound semiconductor layer and includes the second compound semiconductor layer, and a fourth photoelectric conversion element that photoelectrically converts the infrared light that has passed through the third light transmitting part, and
the second compound semiconductor layer is different in film thickness between the second light transmitting part and the third light transmitting part.

13. The solid-state imaging device according to claim 1, wherein each of the first and second light transmitting parts includes a transparent electrode, the transparent electrode being provided on side of the second compound semiconductor layer remote from the first compound semiconductor layer in common for the first and second pixels and being electrically connected to both the first and second compound semiconductor layers.

14. The solid-state imaging device according to claim 1, wherein the second compound semiconductor layer is wider in band gap than the first compound semiconductor layer.

15. The solid-state imaging device according to claim 1, wherein the second compound semiconductor layer is covalently bonded to the first compound semiconductor layer.

16. The solid-state imaging device according to claim 1, wherein the second compound semiconductor layer and the first compound semiconductor layer include different compound semiconductor materials.

17. The solid-state imaging device according to claim 1, wherein
the second compound semiconductor layer includes any one of InGaAs, GaAsSb, InGaAsP, InGaAlAs, InP, InAlAs, InAlAsSb, AlAsSb, AlAsSb, InAsP, or InSbP.

18. The solid-state imaging device according to claim 1, wherein the first compound semiconductor layer includes any one of InGaAs, Ex. InGaAs, or an InGaAs/GaAsSb superlattice.

19. The solid-state imaging device according to claim 1, wherein the first and second light transmitting parts are alternately and repeatedly arranged in each of an X direction and a Y direction orthogonal to each other in plan view.

20. An electronic device comprising:
a solid-state imaging device; an optical lens that forms an image of image light from a subject on an imaging surface of the solid-state imaging device; and a signal processing circuit that performs signal processing on a signal output from the solid-state imaging device, wherein
the solid-state imaging device includes
a pixel region in which a plurality of pixels is arranged in a matrix,
the plurality of pixels includes a first pixel and a second pixel,
the first pixel includes a first light transmitting part that is provided on a light incident surface side of a first compound semiconductor layer and transmits infrared light and visible light, and a first photoelectric conversion element that is provided in the first compound semiconductor layer and photoelectrically converts the infrared light and the visible light that have passed through the first light transmitting part, and
the second pixel includes a second light transmitting part including a second compound semiconductor layer, the second light transmitting part being provided on the light incident surface side of the first compound semiconductor layer and transmitting the infrared light and blocking the transmission of the visible light, and a second photoelectric conversion element that photoelectrically converts the infrared light that has passed through the second light transmitting part.
